(19) United States
(12) Patent Application Publication
(10) Pub. No.: US 2025/0268094 A1
(43) Pub. Date: Aug. 21, 2025

(54) THIN FILM, PHOTOELECTRIC DEVICE AND DISPLAY DEVICE

(71) Applicant: TCL Technology Group Corporation, Huizhou, Guangdong (CN)

(72) Inventors: Wenjun HOU, Huizhou, Guangdong (CN); Yixing YANG, Huizhou, Guangdong (CN)

(73) Assignee: TCL Technology Group Corporation, Huizhou, Guangdong (CN)

(21) Appl. No.: 18/858,238

(22) PCT Filed: Dec. 28, 2022
(86) PCT No.: PCT/CN2022/142975

§ 371 Date: Oct. 18, 2024

(30) Foreign Application Priority Data
Apr. 20, 2022 (CN) 202210419136.0
Apr. 20, 2022 (CN) 202210419148.3
Apr. 20, 2022 (CN) 202210420932.6
Apr. 20, 2022 (CN) 202210420936.4
Apr. 20, 2022 (CN) 202210420939.8

(51) Int. Cl. H10K 85/10; H10K 50/15; H10K 101/30

(52) U.S. Cl. CPC H10K 85/111; H10K 50/15; H10K 2101/30

(57) ABSTRACT

Disclosed in the present application are a thin film, a photoelectric device and a display device. The thin film comprises a first polymer; the first polymer is a block copolymer formed by a fluorene-containing group and an aniline-containing group; the fluorene-containing group and the aniline-containing group in the first polymer can impart the hole transport performance to the thin film, and by controlling the contents of the fluorene-containing group and the aniline-containing group, a highest occupied molecular orbital energy level of the thin film can be adjusted, and a better hole mobility is achieved.

This application claims priority benefits to the following Chinese patent applications:

Chinese Patent Application No. 202210420932.6, filed in the China National Intellectual Property Administration on Apr. 20, 2022, and entitled “HOLE TRANSPORT THIN FILM, PHOTOELECTRIC DEVICE AND PREPARATION METHOD THEREOF, AND DISPLAY DEVICE”;

Chinese Patent Application No. 202210419136.0, filed in the China National Intellectual Property Administration on Apr. 20, 2022, and entitled “HOLE TRANSPORT THIN FILM, PHOTOELECTRIC DEVICE AND PREPARATION METHOD THEREOF, AND DISPLAY DEVICE”;

Chinese Patent Application No. 202210420936.4, filed in the China National Intellectual Property Administration on Apr. 20, 2022, and entitled “HOLE TRANSPORT THIN FILM, PHOTOELECTRIC DEVICE AND PREPARATION METHOD THEREOF, AND DISPLAY DEVICE”;

Chinese Patent Application No. 202210419148.3, filed in the China National Intellectual Property Administration on Apr. 20, 2022, and entitled “THIN FILM, PHOTOELECTRIC DEVICE AND DISPLAY DEVICE”;

Chinese Patent Application No. 202210420939.8, filed in the China National Intellectual Property Administration on Apr. 20, 2022, and entitled “HOLE TRANSPORT THIN FILM, PHOTOELECTRIC DEVICE AND PREPARATION METHOD THEREOF, AND DISPLAY DEVICE”;
which are incorporated herein by reference in its entirety.

### TECHNICAL FIELD

The present disclosure relates to the field of display technologies, and more particularly, to a thin film, a photoelectric device, and a display device.

### BACKGROUND

Photoelectric devices have a wide range of applications in fields of new energy, sensing, communication, display, and lighting. For example, solar cells, photodetectors, organic electro-photoelectric device (OLED) or quantum dot electro-photoelectric device (QLED).

The structure of conventional photoelectric device mainly includes an anode, a hole injection layer, a hole transport layer (i.e. a hole transport thin film), a light-emitting layer, an electron transport layer, an electron injection layer, and a cathode. Under the action of the electric field, the holes generated by the anode move and inject into the hole transport layer, and the electrons generated by the cathode of the photoelectric device move and inject into the hole transport layer and the electron transport layer, and finally the holes and the electrons migrate to the light-emitting layer. When the holes and the electrons meet in the light-emitting layer, energy excitons are generated, thereby exciting the light-emitting molecules to finally produce visible light. The current efficiencies of existing photoelectric devices need to be improved.

### Technical Solutions

Therefore, the present disclosure provides a thin film, a photoelectric device, and a display device.

Embodiments of the present disclosure provide a thin film, the thin film includes a first polymer including a fluorene-containing group and an aniline-containing group.

Correspondingly, the present disclosure further provides a photoelectric device including a cathode, a light-emitting layer, a hole transport thin film and an anode sequentially stacked, wherein the hole transport thin film is the above-described thin film

Correspondingly, the present disclosure further provides a display device including the above-described photoelectric device.

### BRIEF DESCRIPTION OF FIGURES

In order to more clearly explain the technical solutions in the embodiments of the present disclosure, the figures to be used in the description of the embodiments are briefly described below. It is apparent that the figures in the following description are merely some embodiments of the present disclosure. For those skilled in the art, without involving any creative effort, other figures may be obtained based on these figures.

FIG. 1 is a structural schematic diagram of a photoelectric device according to an embodiment of the present disclosure;

FIG. 2 is a flowchart of a preparation method for a photoelectric device according to an embodiment of the present disclosure;

FIG. 3 is an energy level schematic diagram of each functional layer of the photoelectric device according to Example 1 of the present disclosure;

FIG. 4 is an energy level schematic diagram of each functional layer of the photoelectric device according to Example 2 of the present disclosure;

FIG. 5 is an energy level schematic diagram of each functional layer of the photoelectric device according to Example 3 of the present disclosure;

FIG. 6 is an energy level schematic diagram of each functional layer of the photoelectric device according to Comparative Example 1 of the present disclosure;

FIG. 7 is an energy level schematic diagram of each functional layer of the photoelectric device according to Example 4 of the present disclosure;

FIG. 8 is an energy level schematic diagram of each functional layer of the photoelectric device according to Example 5 of the present disclosure;

FIG. 9 is an energy level schematic diagram of each functional layer of the photoelectric device according to Example 6 of the present disclosure;

FIG. 10 is a current efficiency test curve diagram of the photoelectric device according to Example 7 of the present disclosure;

FIG. 11 is a current efficiency test curve diagram of the photoelectric device according to Example 8 of the present disclosure;

FIG. 12 is a current efficiency test curve diagram of the photoelectric device according to Example 9 of the present disclosure;

FIG. 13 is a current efficiency test curve diagram of the photoelectric device according to Comparative Example 2 of the present disclosure;

FIG. 14 is a current efficiency test curve diagram of the photoelectric device according to Comparative Example 3 of the present disclosure;

FIG. 15 is a schematic diagram of HOMO energy level matching of each functional layer according to an embodiment of the present disclosure;

FIG. 16 is a current efficiency test curve diagram of the photoelectric device according to Example 10 of the present disclosure;

FIG. 17 is a current efficiency test curve diagram of the photoelectric device according to Example 11 of the present disclosure;

FIG. 18 is a current efficiency test curve diagram of the photoelectric device according to Example 12 of the present disclosure;

FIG. 19 is a current efficiency test curve diagram of the photoelectric device according to Comparative Example 4 of the present disclosure;

FIG. 20 is a current efficiency test curve diagram of the photoelectric device according to Comparative Example 5 of the present disclosure;

FIG. 21 is a fluorescence emission spectrum diagram of a first polymer A untreated with a chlorobenzene solvent and a first polymer A treated with a chlorobenzene solvent in Experimental Example 1 of the present disclosure;

FIG. 22 is a fluorescence emission spectrum diagram of a first polymer B untreated with a chlorobenzene solvent and a first polymer B treated with a chlorobenzene solvent in Experimental Example 1 of the present disclosure;

FIG. 23 is current density-current efficiency characteristic curves diagram of photoelectric devices according to Example 21, Example 25, and Comparative Example 6 in Experimental Example 2 of the present disclosure.

### EMBODIMENTS OF THE PRESENT DISCLOSURE

Technical solutions in embodiments of the present disclosure will be clearly and completely described below with reference to the figures in the embodiments of the present disclosure. It is apparent that, the described embodiments are only a part of embodiments of the present disclosure, rather than all the embodiments. Based on the embodiments in the present disclosure, all other embodiments obtained by those skilled in the art without creative effort fall within the protection scope of the present disclosure.

Hereinafter, each of them will be described in detail. It should be noted that the order of description of the following embodiments is not intended to limit the preferred order of the embodiments. In addition, in the description of the present disclosure, the term “comprising” means “including but not limited to”.

In the present disclosure, “and/or” describes the association relationship of the association object, and indicates that there may be three kinds of relationships, for example, A and/or B, which may indicate that A exists alone, A and B exist at the same time, and B exists alone. A and B may be singular or plural.

In the present disclosure, the terms “one or more” refer to one or more of the listed items, and “a plurality of/multiple” refers to any combination of two or more of these items, including any combination of a single item (species) or a plurality of items (species). For example, “at least one of a, b, or c” or “at least one of a, b, and c” may mean a, b, c, a-b (that is, a and b), a-c, b-c, or a-b-c, wherein a, b, and c may be a single item or a plurality of items, respectively.

In the present disclosure, “weight average molecular weight” refers to the averaged molar weight value in a polymer is statistically by weight.

Various embodiments of the present disclosure may be presented in a form of range. It should be understood that the description in the form of range is merely for convenience and brevity, and should not be construed as a hard limitation on the scope of the disclosure. Therefore, it should be considered that the recited range description has specifically disclosed all possible subranges, as well as a single numerical value within that range. For example, it should be considered that a description of a range from 1 to 6, more specifically, a range such as from 1 to 3, from 1 to 4, from 1 to 5, from 2 to 4, from 2 to 6, from 3 to 6, etc., and a single number within the range, such as 1, 2, 3, 4, 5, and 6, regardless of the range. Whenever a range of values is indicated herein, it is meant to include any recited number (fraction or integer) within the indicated range.

In photoelectric devices such as QLED devices, since the material of the hole transport is organic material, the material of the electron transport is inorganic materials, and the electron mobility of inorganic nanoparticle is much greater than that of hole mobility, thereby hole transport materials with high hole mobility are needed to match the electron mobility. However, quantum dot luminescent materials generally have deep valence band energy levels, and it is difficult for a single organic hole transport material to meet the energy level difference between the HOMO energy level of the anode or the hole injection layer and the valence band energy level of quantum dots. Double-layer hole transport layers or multilayers of hole transport layers can theoretically solve the above problems, but the actual current efficiency of the device is not high. In addition, hole transport materials with high hole mobility can theoretically improve the above problems, but the actual current efficiency of the device is not high.

In photoelectric devices such as QLED devices, since the material of the hole transport is organic material, the material of the electron transport is inorganic materials, and the electron mobility of inorganic nanoparticle is much greater than that of hole mobility, which will cause a large amount of charge to accumulate at the interface between the hole transport layer and the quantum dot light-emitting layer, resulting in a small amount of electrons transitioning to the hole transport layer under the action of an electric field to form excitons, which accelerates the aging of the hole transport material. Based on this, the present disclosure provides a hole transport thin film as described below, in order to improve the problem of accelerated aging of the hole transporting material due to electron transition to the hole transporting material of the related art.

Further research by the applicant found that, the current efficiencies of devices with double-layer hole transport layers or multilayers hole transport layers are not high is mainly because the double-layer hole transport layers have interfacial mutual dissolution problems during the wet fabrication process. Based on this, the present disclosure provides a hole transport thin film as described below, in order to improve the problem of low current efficiencies of photoelectric devices made of double-layer hole transport materials or multilayers hole transport materials of the related art.

Further research by the applicant also found that, the current efficiency of the device made of the hole transport material with high hole mobility is not high is mainly because that the quantum dot material modified by ligands has good solubility and stability in the solvent. The quantum dot light-emitting layer is generally formed on the hole transport thin film, due to the good solubility of the quantum dot material, in the manufacturing process, the problem that the quantum dot material penetrates into the hole transport thin film with the solvent is easy to occur, resulting in the interfacial mutual dissolution problems between the light-emitting layer and the hole transport thin film, thus affecting the current efficiency of photoelectric device. Based on this, the present disclosure provides a hole transport thin film as described below in order to improve the problem of low current efficiency of a device made by hole transport materials in the related art.

Technical solutions of the present disclosure are as following:

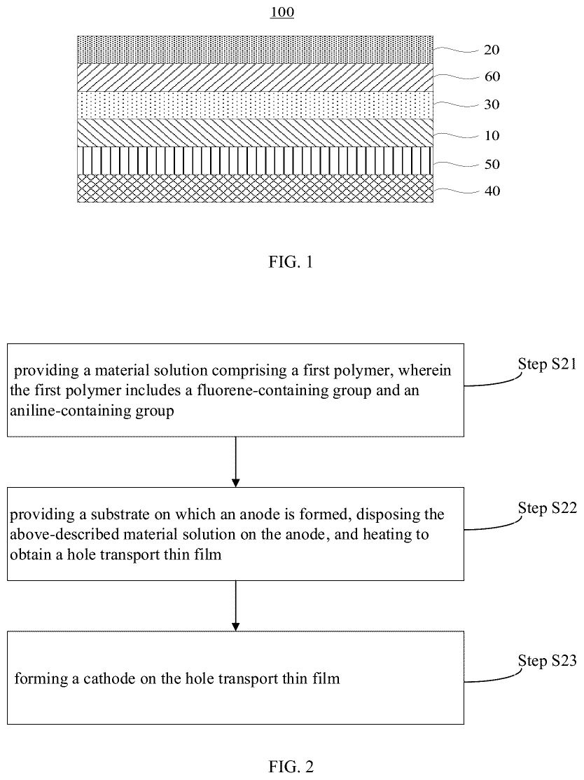

An embodiment of the present disclosure provides a hole transport thin film 10, which is mainly used for a photoelectric device 100. Referring to FIG. 1, FIG. 1 is a structural schematic diagram of a photoelectric device according to an embodiment of the present disclosure. The hole transport thin film 10 includes a first polymer. The first polymer includes a fluorene-containing group and an aniline-containing group.

The fluorene-containing group and the aniline-containing group in the first polymer can impart hole transport performance to the hole transport thin film 10, and by controlling the contents of the fluorene-containing group and the aniline-containing group, the highest occupied molecular orbital (HOMO) energy level of the hole transport thin film 10 can be adjusted to adapt to the HOMO energy level of materials of different light-emitting layers, and a better hole mobility is achieved.

It can be understood that the aniline-containing group may be a diphenylamine-containing group or a triphenylamine-containing group, and the present disclosure is not particularly limited.

As used in the present disclosure, the “fluorene-containing group” includes both unsubstituted fluorenyl group and fluorenyl group in which one or more hydrogen atoms are optionally substituted with other groups, wherein the other groups may be alkyls, and multiple degrees of substitution are allowed.

As used the present disclosure, an “aniline-containing group” refers to an amine group having one or more aryls, that is —NH₂, —NH or a nitrogen atom is attached to an aryl. The “aryl” includes both unsubstituted aryl and aryl in which one or more hydrogen atoms are optionally substituted with other groups. The “unsubstituted aryl” refers to an aromatic group containing only carbon atoms on an aromatic ring, and includes but not limited to phenyl, 1-naphthyl, 2-naphthyl, or biphenyl. The substituted aryl means that one hydrogen atom or more hydrogen atoms on an aromatic group containing only carbon atoms on an aromatic ring are optionally substituted with other groups, such as halogen atoms or alkyls, and multiple degrees of substitution are allowed.

In a first embodiment of the present disclosure, the first polymer is a block copolymer formed by a fluorene-containing group and an aniline-containing group.

The hole transport thin film 10 further includes a second polymer. The second polymer is a block copolymer formed by a fluorene-containing group and an aniline-containing group. From the bottom surface to the top surface of the hole transport tin film 10, the content of the second polymer increases gradually.

Moreover, a mole fraction of the aniline-containing group in the second polymer is smaller than a mole fraction of the aniline-containing group in the first polymer. The hydrogen atoms in the second polymer are wholly or partially substituted with fluorine atoms.

It can be understood that, in embodiments of the present disclosure, in the film formation process of the hole transport thin film 10, the second polymer is more inclined to be located in the upper layer of the hole transport thin film 10 (referring to the structure of FIG. 1) due to the presence of fluorine atoms. This is because the fluorine atom has a large electronegativity, a small atomic radius, a short C—F bond and a bond energy as high as 500 KJ/mol. The mutual repulsion of adjacent fluorine atoms causes the fluorine atoms not to be in a same plane, but to be spirally distributed along the carbon chain. Especially in a perfluorocarbon chain, the sum of the van der Waals radii of two fluorine atoms is about 0.27 nm, basically surrounding and filling the C—C—C bond. The almost void-free space barrier prevents any atoms or groups from entering and destroying the C—C bond. Therefore, during the film formation process of the hole transport thin film 10, fluorine-containing groups tend to be enriched at the interface between the hole transport thin film 10 and the air (a side of the hole transport thin film 10 close to a light-emitting layer), and extend into the air, so that the hole transport thin film 10 forms a gradient molecular structure from the bottom layer (a layer of the hole transport thin film 10 close to the hole injection layer) to the top layer (a layer of the hole transport thin film 10 close to the light-emitting layer). The closer to the top layer, the greater the content of the second polymer, and the closer to the bottom layer, the greater the content of the first polymer. The inside of the hole transport thin film 10 has a gradient molecular structure which is not a traditional double-layer transport thin film formed by two transport thin films, therefore there is no material miscibility problem in material interface and between different transport thin film layers. There are relatively more aniline-containing groups in the first polymer and relatively few aniline-containing groups in the second polymer, thereby the highest occupied molecular orbital (HOMO) energy level of the first polymer is higher, and the HOMO energy level of the second polymer is lower. Corresponding to the gradient molecular structure of the thin film from the bottom layer to the top layer, the hole transport thin film 10 forms a gradient energy level from high to low from the bottom layer to the top layer. The high HOMO energy level of the bottom layer matches the hole injection layer, which facilitates the hole injection layer to inject holes into the hole transport thin film 10. The low HOMO energy level of the top layer reduces the energy level difference between the hole transport thin film 10 and the light-emitting layer, which makes it easier for holes to overcome the potential barrier between the hole transport thin film 10 and the light-emitting layer and transition to the light-emitting layer. Therefore, the hole transport thin film 10 of the embodiment of the present disclosure can improve the hole mobility, and thus can improve the current efficiency of corresponding photoelectric device.

In one embodiment, a material of the hole transport thin film 10 is a composition of a first polymer and a second polymer. The first polymer is a block copolymer formed by a fluorene-containing group and an aniline-containing group. The second polymer is a block copolymer formed by a fluorene-containing group and an aniline-containing group. Moreover, a mole fraction of the aniline-containing group in the second polymer is smaller than a mole fraction of the aniline-containing group in the first polymer, and hydrogen atoms in the second polymer are wholly or partially substituted with fluorine atoms. That is, the material of the hole transport thin film 10 is only the first polymer and the second polymer. It can be understood that, in addition to the first polymer and the second polymer, the material of the hole transport thin film 10 may further include other materials, such as a high thermal conductivity material to enhance the heat dissipation of the hole transport thin film 10, or a magnetic material to enhance the magnetic properties of the hole transport thin film 10.

In one embodiment, structural formulas of the first polymer and the second polymer in the hole transport thin film 10 are as following:

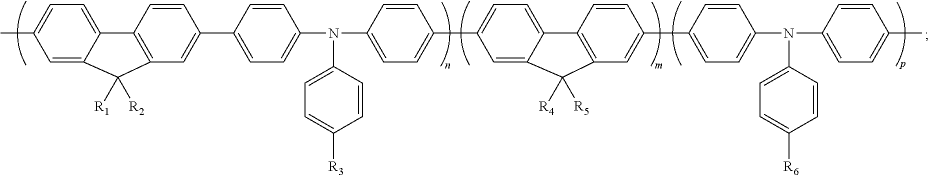

where n>0, m≥0, p≥0; R₁ to R₆ are same groups or different groups, and R₁ to R₆ are independently selected from a C₁-C₂₀ alkyl, an aromatic group, or a heteroaromatic group.

It can be understood that R₁ to R₆ may be same substituents, for example, they can be an alkyl, an aromatic group, or a heteroaromatic group at the same time. R₁ to R₆ may also be different substituents from each other. For convenience of description, a copolymerized repeating unit formed by the fluorene-containing group and the aniline-containing group is referred to as a unit A, a homopolymerized repeating unit formed by the fluorene-containing group is referred to as a unit B, and a homopolymerized repeating unit formed by the aniline-containing group is referred to as a unit C. It can be understood that the block copolymer of the present embodiment may include only the unit A, or may be a block copolymer including the unit A and the unit B, or may be a block copolymer including the unit A and the unit C, or may be a block copolymer including the unit A, the unit B and the unit C at the same time, which is not particularly limited in the embodiment of the present disclosure. The molar fraction of the aniline-containing group may be determined according to the needs of HOMO energy level, and then the corresponding polymer structure may be selected.

It should be noted that the structural formula of the block copolymer of the first polymer and the second polymer can refer to the above structural formula, but the values of n, m, and p in the structure formula of the first polymer and the structure formula of the second polymer are independent of each other, so that the molar fractions of the aniline-containing group in the first polymer and the second polymer can be different. The selection of the substituents (R₁ to R₆) in the structure formula of the first polymer and the structure formula of the second polymer are also independent of each other, that is, the substituents in the first polymer and the second polymer may be the same or different, but no fluorine atom is present in the first polymer.

In one embodiment, in the material of the hole transport thin film 10, the weight average molecular weight of the first polymer is greater than or equal to 50,000 and less than or equal to 250,000, and the weight average molecular weight of the second polymer is greater than or equal to 50,000 and less than or equal to 250,000. The polymerization degree of block copolymer has a great influence on the interfacial mutual dissolution of material. When the weight average molecular weight of the block copolymer is small, the hole transport thin film 10 may be interfacially intersoluble with adjacent functional thin film. When the weight average molecular weight of the block copolymer is too large, the solubility of the first polymer and the second polymer of the hole transport thin film 10 may be reduced, thus affecting the film-forming properties. For example, when the weight average molecular weight of the block copolymer is small, the hole transport thin film 10 may be interfacially intersoluble with the hole injection layer, or the hole transport thin film 10 may be interfacially intersoluble with the light-emitting layer. Therefore, the weight average molecular weight of the block copolymer is preferably greater than or equal to 50,000, which can prevent interfacial mutual dissolution between the hole transport thin film 10 and the adjacent functional thin film.

In one embodiment, the HOMO energy level of the first polymer is greater than or equal to −5.3 eV and less than −4.8 eV. The HOMO energy level of the second polymer is greater than −5.8 eV and less than −5.3 eV. The first polymer is mainly located in the layer of the hole transport thin film 10 close to the hole injection layer, thereby when the HOMO energy level of the first polymer is −5.3 eV˜−4.8 eV, the bottom layer of the hole transport thin film 10 can be better matched with the HOMO energy level of the hole injection layer, thereby the injection efficiency of holes from the hole injection layer to the hole transport thin film 10 can be improved. The second polymer is mainly located in the layer of the hole transport thin film 10 close to the light-emitting layer, thereby when the HOMO energy level of the second polymer is −5.8 eV˜−5.3 eV, the energy level difference between the hole transport thin film 10 and the light-emitting layer can be reduced as compared to using the first polymer alone as the hole transport thin film 10, so that holes can more easily cross the potential barrier from the hole transport thin film 10 to the light-emitting layer, and the hole mobility can be improved.

In one embodiment, a mole fraction of the aniline-containing group in the first polymer is greater than or equal to 50% and less than 100%. A mole fraction of the aniline-containing group in the second polymer is less than 50% and greater than 0. It should be noted that the higher the content of the aniline-containing unit in a polymer, the higher the HOMO energy level of the polymer. For example, when the molar fraction of the aniline-containing unit approaches 100%, that is, p is much larger than n and m in the structural formula of the block copolymer, the HOMO energy level of the block copolymer approaches the HOMO energy level of the polyaniline (−4.8 eV). When the mole fraction of the aniline-containing unit is 0%, that is, m is much larger than n and p in the structural formula of the block copolymer, the HOMO energy level of the block copolymer is close to the HOMO energy level of the polyfluorene (−5.8 eV). In the hole transport thin film 10 of the present disclosure, the mole fraction of the aniline-containing group in the first polymer is greater than or equal to 50% and less than 100%, which can make the HOMO energy level of the layer of the hole transport thin film 10 close to the hole injection layer can be between −5.3 eV and −4.8 eV, thereby the energy level difference between the hole transport thin film 10 and the hole injection layer can be reduced to an appropriate range, and it is beneficial to improving the hole injection efficiency. The molar fraction of the aniline-containing group in the second polymer is greater than 0 and less than 50%, which can make the HOMO energy level of the layer of the hole transport thin film 10 close to the light-emitting layer can be between −5.8 eV and −5.3 eV, thereby the energy level difference between the hole transport thin film 10 and the light-emitting layer can be reduced to an appropriate range, and it is beneficial to improving the hole mobility.

In one embodiment, a weight percentage of the first polymer ranges from 1% to 20%, and a weight percentage of the second polymer ranges from 80% to 99%. The first polymer is mainly concentrated in the lower layer of the hole transport thin film 10, that is, the layer of the hole transport thin film 10 close to the hole injection layer, and the molar fraction of the aniline-containing unit in the first polymer is high, if the amount of the first polymer is added too much, the HOMO energy level of the upper layer is greatly affected, thereby the efficiency of the hole transition of the upper layer of the hole transport thin film 10 to the light-emitting layer is affected. Therefore, in the present embodiment, the weight percentages of the first polymer set to 1%˜20%, and the weight percentages of the second polymer is set to 80%˜99%.

In a second embodiment of the present disclosure, the first polymer is a block polymer including a first block and a second block. The first block is a copolymerized block formed by a fluorene-containing group and an aniline-containing group. The second block is a copolymerized block formed by a fluorene-containing group and an aniline-containing group. The aniline-containing group in the second block is connected with an electron-donating group. The hydrogen atoms in the first polymer are wholly or partially substituted with fluorine atoms.

The hole transport thin film 10 further includes a third polymer. The third polymer is a conductive polymer material.

It can be understood that, in the embodiment of the present disclosure, in the process of making the hole transport thin film 10 from the material of the hole transport thin film 10, the first polymer is more inclined to be located in the upper layer of the hole transport thin film 10 due to the presence of fluorine atoms (referring to the structure of FIG. 1). This is because the fluorine atom has a large electronegativity, a small atomic radius, a short C—F bond, and a bond energy as high as 500 KJ/mol. The mutual repulsion of adjacent fluorine atoms causes the fluorine atoms not to be in a same plane, but to be spirally distributed along the carbon chain. Especially in a perfluorocarbon chain, the sum of the van der Waals radii of two fluorine atoms is about 0.27 nm, which basically surrounding and filling the C—C—C bond. The almost void-free space barrier prevents any atoms or groups from entering and destroying the C—C bond. Therefore, during the film formation process, fluorine-containing groups tend to be enriched at the interface between the hole transport thin film 10 and the air (a side of the hole transport thin film 10 close to the light-emitting layer), and extend into the air, thereby the closer to the top layer (a layer of the hole transport thin film 10 close to a light-emitting layer), the more the first polymer.

When the hole transport thin film 10 is used as a hole transport layer of a photoelectric device, since the first polymer mainly located in the top layer contains the electron-donating group, the LUMO (lowest unoccupied molecular orbital) energy level of the top layer of the hole transport thin film 10 can be increased, and the increase of the LUMO energy level of the top layer of the hole transport thin film 10 increases the difficulty of electron transition from the light-emitting layer to the hole transport layer, thereby reducing the aging rate of the hole transport layer and improving the lifetime of the photoelectric device.

As an example, along the thickness direction of the hole transport thin film 10, the content of the first polymer increases or decreases from one surface to another surface. For example, taking the photoelectric device shown in FIG. 1 as an example, the hole transport thin film 10 can be formed by a wet film formation. During the wet film formation process, fluorine-containing groups tend to be enriched on the surface of the hole transport thin film 10 (that is, a surface of the hole transport thin film 10 close to the light-emitting layer), thereby the hole transport thin film 10 can form a gradient molecular structure from the bottom layer (a layer of the hole transport thin film 10 close to the hole injection layer) to the top layer (a layer of the hole transport thin film 10 close to the light-emitting layer). The closer to the bottom layer, the greater the content of the third polymer, and the closer to the top layer, the greater the content of the first polymer. The first polymer mainly located in the top layer of the hole transport thin film 10 contains the electron-donating group, thereby the LUMO energy level of the top layer of the hole transport thin film 10 can be improved. Corresponding to the gradient molecular structure from the bottom layer to the top layer of the hole transport thin film 10, the hole transport thin film 10 can form a gradient LUMO energy level that gradually increases from the bottom layer to the top layer. The increase of LUMO energy level in the top layer of the hole transport thin film 10 increases the difficulty of electron transition from the light-emitting layer to the hole transport layer, which can reduce the aging rate of the hole transport layer and improve the lifetime of the photoelectric device.

In one embodiment, the material of the hole transport thin film 10 is a composition of the first polymer and the third polymer. The third polymer is a conductive polymer material. The first polymer is a block polymer including a first block and a second block. The first block is a copolymerized block formed of a fluorene-containing group and an aniline-containing group. The second block is a copolymerized block formed of a fluorene-containing group and an aniline-containing group. The aniline-containing group in the second block is connected with an electron-donating group. The hydrogen atoms in the first polymer are wholly or partially substituted with fluorine atoms. That is, the material of the hole transport thin film 10 is only the third polymer and the first polymer.

It can be understood that, in addition to the first polymer and the third polymer, the material of the hole transport thin film 10 may further include other materials, such as a high thermal conductivity material to enhance the heat dissipation of the hole transport thin film 10, or a magnetic material to enhance the magnetic properties of the hole transport thin film 10.

In one embodiment, the conductive polymer material may be polyaniline, polythiophene, polyfluorene, or a copolymer. The copolymer is formed by at least two of polyaniline, polythiophene, and polyfluorene. For example, the polyaniline may be poly [N,N′-bis(4-butylphenyl)-N,N′-bis(phenyl)-benzi (poly-TPD). The polythiophene may be poly(3,4-ethylenedioxythiophene)-poly(styrenesulfonate) (PEDOT:PSS). The polyfluorene may be poly [(4-butylphenyl) iMino]-1,4-phenylene [(4-butylphenyl)iMinChemicalbooko]-1,4-phenylene (9,9-dioctyl-9H-fluorene-2,7-diyl)-1,4-phenylene] (PFB), Poly(9,9-dioctylfluorene-co-N-(4-butylphenyl)diphenylamine) (TFB), and the like. The conductive polymer material may be one or more of the above materials, or may be a block copolymer including corresponding functional groups, and the embodiments of the present disclosure are not particularly limited.

In one embodiment, a mole fraction of the second block in the first polymer is greater than or equal to 0.1% and less than or equal to 15%. The aniline-containing group of the second block is connected with an electron-donating group, if the molar fraction of the second block is too high, the content of the electron-donating group will also increase, and when there are too many electron-donating groups, the hole transport efficiency of the hole transport thin film 10 will be reduced. Therefore, the mole fraction of the second block in the second polymer is preferably not more than 15%.

In one embodiment, the LUMO energy level of the first polymer is greater than or equal to −2.5 eV and less than or equal to −1.8 eV. For example, the LUMO energy level of the first polymer may be −2.5 eV, −2.3 eV, −2.2 eV, −2.0 eV, −1.9 eV, −1.8 eV, etc. The first polymer is mainly located in the layer of the hole transport thin film 10 close to the light-emitting layer. When the LUMO energy level of the first polymer meets the above conditions, the LUMO energy level difference between the hole transport thin film 10 and the light-emitting layer can be made to exceed 1.5 eV, thereby, the probability of electrons transitioning from the light-emitting layer to the hole transport thin film 10 can be reduced. In addition, the HOMO energy level of the first polymer is preferably less than or equal to −5.2 eV. For example, the HOMO energy level of the first polymer can be −5.2 eV, −5.3 eV, −5.4 eV, etc. The higher the mole fraction of the aniline-containing group, the higher the HOMO energy level of the first polymer. Therefore, the HOMO energy level of the first polymer can be adjusted by adjusting the mole fraction of the aniline-containing group, so that the HOMO energy level of the top layer of the hole transport thin film 10 is closer to the light-emitting layer, thereby the hole mobility is improved.

In one embodiment, in the material of the hole transport thin film 10, the first polymer has a structural formula as following:

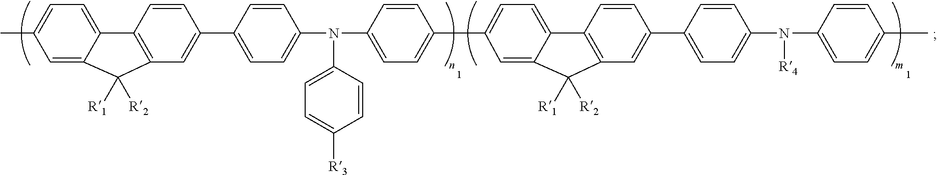

where a mole fraction of the first block is n₁, a mole fraction of the second block is m₁, and 0.001≤m₁≤0.15;
R₁′ to R₃′ are same groups or different groups; and R₁′ to R₃′ are independently selected from a C₁-C₂₀ alkyl, an aromatic group, or a heteroaromatic group; R₄′ is an electron-donating group with a heterocyclic structure.

It can be understood that R₁′ to R₃′ may be same substituents, for example, they can be alkyls, aromatic groups, or heteroaromatic groups at the same time. R₁′ to R₃′ may also be different substituents from each other. The copolymerized repeating unit formed by the fluorene-containing group and the triphenylamine-containing group is a first block, the copolymerized repeating unit formed by the fluorene-containing group and the diphenylamine-containing group is a second block, and the R₄′ in the second block is an electron-donating group. For example, the electron-donating group may be a dialkylamino group (—NR₂), an alkylamino group (—NHR), an amino group (—NH₂), a hydroxy group (—OH), an alkoxy group (—OR), an amide group (—NHCOR), an acyloxy group (—OCOR), and the like. Preferably, the electron-donating group of the present disclosure is an electron-donating group with a heterocyclic structure. For example, the electron-donating group with a heterocyclic structure may be selected from one or more of a carbazole group, a triazole group, and a triazine group. When the electron-donating group with a heterocyclic structure is selected from the above two or three groups, it can be understood that the second block includes two or three sub-blocks, and each of the sub-blocks includes an electron-donating group. Heteroatoms can increase the electron cloud density of the carbon atoms on the ring and increase the LUMO energy level of the top layer of the hole transport thin film 10, thereby preventing the probability of electrons transition from the light-emitting layer to the hole transport thin film 10. When the content of the heteroatoms is not particularly high, the hole transport efficiency will not be affected.

In one embodiment, in the material of the hole transport thin film 10, the first polymer further includes a third block including a first self-crosslinking group. As described above, the hole transport thin film 10 forms a gradient molecular structure from the bottom layer (a layer of the hole transport thin film 10 close to the hole injection layer) to the top layer (a layer of the hole transport thin film 10 close to the light-emitting layer). The closer to the bottom layer, the greater the content of the third polymer, and the closer to the top layer, the greater the content of the first polymer. The first polymer further includes the first self-crosslinking group, a self-crosslinking reaction will occur when the hole transport thin film 10 is formed, so that a layer of the hole transport thin film 10 close to the light-emitting layer mainly includes a cross-linked polymer, which has better solvent resistance and can prevent the material components of the light-emitting layer from penetrating into the hole transport thin film 10 to reduce the hole transport efficiency. The hole transport thin film 10 of the present embodiment can increase the difficulty of electron transition from the light-emitting layer to the hole transport thin film 10, thereby reducing the aging rate of the hole transport thin film 10. Moreover, the hole transport thin film 10 of the present embodiment can also reduce the occurrence of interfacial mutual dissolution between the hole transport thin film 10 and the light-emitting layer, thereby improving the current efficiency.

In one embodiment, a structural formula of the first polymer is as following:

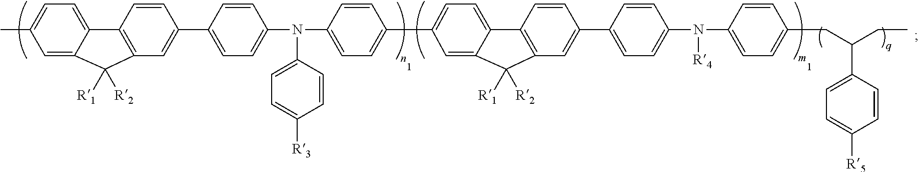

where a mole fraction of the third block is q, 0.001≤m₁≤0.15, 0<q≤0.05, and R₅′ is a first self-crosslinking group containing a crosslinking bond.

It can be understood that the group including R₅′ described above is a third block. The crosslinking bond in R₅′ may form a cross-linked structure inside the first polymer. R₅′ may be a group containing a thermal crosslinking bond, and the crosslinking reaction is carried out by heating. R₅′ may also be a group containing a crosslinking bond responsive to ultraviolet light, and the crosslinking reaction is carried out by irradiation with ultraviolet light. It should be noted that the first self-crosslinking group does not have electrical conductivity, thereby the mole fraction of the third block should not be higher than 5%. If the content of the first self-crosslinking group is too high, the electron transport efficiency will be significantly reduced.

In one embodiment, R₅′ in the first polymer is one of the following structural formulas:

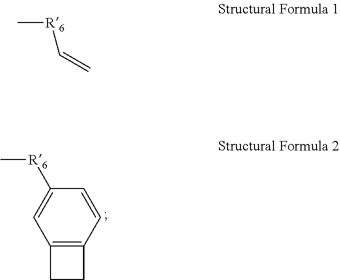

where R₆′ is a C₁-C₂₀ alkyl; or R₆′ is a C₁-C₂₀ alkyl, and one or more carbon atoms are substituted with heteroatoms. When a plurality of carbon atoms are substituted with heteroatoms, the heteroatoms are located in a non-adjacent position. In the above R₅′ group, the double bond in Structural Formula 1 may undergo an addition reaction to form a cross-linked structure between second polymers. The molecular structure of Structural Formula 2 will be isomerized when heated, and the reaction formula is as following:

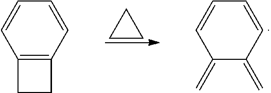

After isomerization, two double bonds are formed, and a crosslinking reaction can be carried out between the first polymers to obtain a cross-linked polymer. The cross-linked structure has better solvent resistance and can prevent small molecules in the light-emitting layer from infiltrating into the hole transport thin film 10 (that is interfacial mutual dissolution), thereby improving the hole mobility and the stability of the photoelectric device.

In one embodiment, the weight average molecular weight of the material of the hole transport thin film 10 is greater than or equal to 50,000 and less than or equal to 250,000. For example, the weight average molecular weight of the first polymer or the third polymer may be 50,000, 70,000, 90,000, 120,000, 150,000, 180,000, 200,000, 230,000, 250,000, etc. If the weight average molecular weight of the first polymer or the third polymer is too small, interfacial mutual dissolution between the hole transport thin film 10 and the functional layer adjacent thereto may occur, and the luminous efficiency may be affected. For example, when the weight average molecular weight of the first polymer or the third polymer is small, the hole transport thin film 10 may be interfacially intersoluble with the hole injection layer, or the hole transport thin film 10 may be interfacially intersoluble with the light-emitting layer. If the weight average molecular weight of the first polymer or the third polymer is too large, the solubility of the first polymer or the third polymer in the solvent and the subsequent wet film forming process will be affected.

In a third embodiment of the present disclosure, the first polymer further includes a group containing a first crosslinking group, in other words, the first polymer includes a fluorene-containing group, an aniline-containing group, and a group containing a first crosslinking group.

The hole transport thin film 10 further includes a crosslinking compound. The crosslinking compound includes a main chain, and at least two second crosslinking groups connected to the main chain. Hydrogen atoms in the crosslinking compound are wholly or partially substituted with fluorine atoms. The second crosslinking group and the first crosslinking group may undergo a crosslinking reaction to cause the first polymer to form a cross-linked structure of.

It can be understood that among the materials of the hole transport thin film 10 of the embodiments of the present disclosure, the fluorene-containing group and the aniline-containing group in the first polymer can impart hole transport performance to the hole transport thin film 10, and through controlling the contents of the fluorene-containing group and the aniline-containing group, the highest occupied molecular orbital (HOMO) energy level of the hole transport thin film 10 can be adjusted to adapt to the HOMO energy level of materials of different light-emitting layers, and a better hole mobility is achieved. In the process of forming the first polymer and the crosslinking compound into the hole transport thin film 10, the second crosslinking group in the crosslinking compound can undergo a crosslinking reaction with the first crosslinking group in the first polymer. Since the crosslinking compound contains at least two second crosslinking groups, and the first polymer contains one first crosslinking group, the crosslinking compound can link at least two first polymer molecules to form a cross-linked structure in the hole transport thin film 10. It should be noted that due to the complexity of polymer chemical reactions, the above-described crosslinking reaction may not necessarily proceed 100% according to an ideal crosslinking reaction model, and some cross-linked compound molecules may link only one first polymer molecule, but at least a certain proportion of cross-linked structures can be formed. At the same time, due to the presence of fluorine atoms in the crosslinking compound, the crosslinking compound is more inclined to be located in the upper layer of the hole transport thin film 10 (referring to the structure of FIG. 1), that is, a layer of the hole transport thin film 10 close to the light-emitting layer is dominated by the cross-linked structure. The cross-linked structure has good solvent resistance and can prevent the material component of the light-emitting layer from penetrating into the hole transport thin film 10, thereby reducing the occurrence of interfacial mutual dissolution between the hole transport thin film 10 and the light-emitting layer, thus improving the current efficiency of the photoelectric device.

As an example, along the thickness direction of the hole transport thin film 10, a content of the crosslinking compound increases or decreases from one surface to another surface. For example, taking the photoelectric device shown in FIG. 1 as an example, the hole transport thin film 10 can be formed by a wet film formation. During the wet film formation process, fluorine-containing groups tend to be enriched on the surface of the hole transport thin film 10 (that is, a surface of the hole transport thin film 10 close to the light-emitting layer), thereby the hole transport thin film 10 can form a gradient cross-linked structure from the bottom layer (a layer of the hole transport thin film 10 close to the hole injection layer) to the top layer (a layer of the hole transport thin film 10 close to the light-emitting layer). The closer to the bottom layer, the greater the content of the first polymer, that is, the layer of the hole transport thin film 10 close to the hole injection layer mainly includes a non-cross-linked structure. The closer to the top layer, the more crosslinking compounds, and the cross-linked structure formed by the crosslinking compounds can prevent the material components of the light-emitting layer from penetrating into the hole transport thin film 10, thereby reducing the occurrence of interfacial mutual dissolution between the hole transport thin film 10 and the light-emitting layer, thus improving the current efficiency of the photoelectric device.

In one embodiment, the material of the hole transport thin film 10 is a composition of the first polymer and the crosslinking compound. The first polymer includes a fluorene-containing group, an aniline-containing group, and a group containing a first crosslinking group. The crosslinking compound includes a main chain, and at least two second crosslinking groups connected to the main chain. The second crosslinking group and the first crosslinking group may undergo a crosslinking reaction. Hydrogen atoms in the crosslinking compound are wholly or partially substituted with fluorine atoms. For example, when the crosslinking compound includes two second crosslinking groups, the crosslinking compound may be linked to the first crosslinking groups of two first polymers through two second crosslinking groups respectively, and the crosslinking compound may be linked between the two first polymers to form a cross-linked structure. When the crosslinking compound includes three second crosslinking groups, one crosslinking compound molecule may connect three first polymer molecules. Due to the complexity of the polymer chemical reaction, the crosslinking reaction may not necessarily proceed 100% according to an ideal crosslinking reaction model, and some crosslinking compound molecules may also link only one or two first polymer molecules, but at least a certain proportion of the cross-linked structure may be formed. In the present embodiment, the material of the hole transport thin film 10 may be only the first polymer and the crosslinking compound. It can be understood that, in addition to the first polymer and the crosslinking compound, the material of the hole transport thin film 10 may further include other materials, such as a high thermal conductivity material to enhance the heat dissipation of the hole transport thin film 10, or a magnetic material to enhance the magnetic properties of the hole transport thin film 10.

In one embodiment, a structural formula of the first polymer in the hole transport thin film 10 is as following:

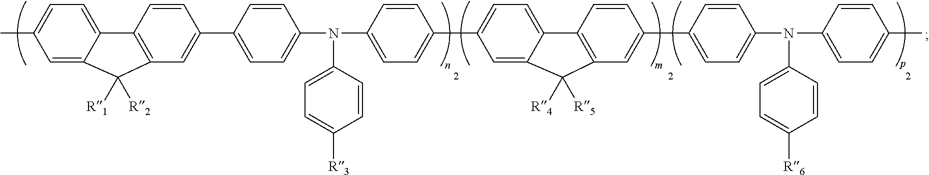

where n₂, m₂, and p₂ are mole fractions, n₂+m₂+p₂=1, 0<n₂<0.95, 0≤m₂<0.95, 0<p₂<0.05; R₁″ to R₅″ are same groups or different groups, and R₁″ to R₅″ are independently selected from a C₁-C₂₀ alkyl, an aromatic group or a heteroaromatic group; R6″ is a first crosslinking group.

It can be understood that R₁″ to R₅″ may be same substituents, for example, they can be alkyls, aromatic groups, or heteroaromatic groups at the same time. R₁″ to R₅″ may also be different substituents from each other. For convenience of description, a copolymerized repeating unit formed by the fluorene-containing group and the triphenylamine-containing group is referred to as a unit A, a homopolymerized repeating unit formed by the fluorene-containing group is referred to as a unit B, and a homopolymerized repeating unit formed by the triphenylamine-containing group is referred to as a unit C. It can be understood that the first polymer of the present embodiment may be a block copolymer including the unit A and the unit B, or a block copolymer including the unit A, the unit B and the unit C at the same time, which is not particularly limited in the embodiment of the present disclosure. The mole fraction of the unit C can be determined according to the number of cross-linked structures, and then the corresponding first polymer structure is selected. It should be noted that the mole fraction of the unit C should be less than 5%, so as to avoid the reduction of the current efficiency of the photoelectric device caused by the excessive proportion of crosslinking groups.

In one embodiment, a structural formula of the crosslinking compound in the material of the hole transport thin film 10 is as following:

R₈″—R₉″—R₁₀″;
where R₉″ is a C₁-C₂₀ alkyl; or R₉″ is a C₁-C₂₀ alkyl, and one or more carbon atoms are substituted with heteroatoms, when a plurality of carbon atoms are substituted with heteroatoms, the heteroatoms are located in a non-adjacent position; R₈″ and R₁₀″ are same or different second crosslinking groups.

It can be understood that the cross-linked compound of the present embodiment has R₉″ as the main chain. The main chain mainly includes a flexible alkyl group, and the flexible alkyl may include heteroatoms. Both ends of the main chain are connected to a second crosslinking group R₈″ and a second crosslinking group R₁₀″, respectively, and for a total of two second crosslinking groups. It should be noted that R₈″ and R₁₀″ may be second crosslinking groups having the same structure, or second crosslinking groups having different structures. By providing second crosslinking groups at both ends of the main chain of the hole transport thin film 10, a network-like cross-linked structure can be formed inside the hole transport thin film 10, thereby the solvent resistance of the hole transport thin film 10 can be improved to better prevent the material component of the light-emitting layer from penetrating into the hole transport thin film 10.

In one embodiment, a chemical formula of the first crosslinking group R₆″ in the block copolymer is the following Chemical Formula 2, Chemical Formula 3 or Chemical Formula 4:

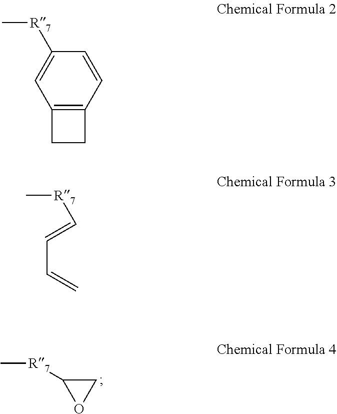

where R₇″ is a C₁-C₂₀ alkyl, an aromatic group, or a heteroaromatic group.

In the present embodiment, the phenylcyclohexane structure of Chemical Formula 2 can be isomerized under heating, and after isomerization, two double bonds are formed to form a first crosslinking bond, and the first crosslinking bond can undergoes a crosslinking reaction with the crosslinking compound. The phenylcyclohexane isomerization reaction formula is as following:

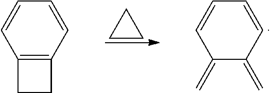

In addition, both the double bond of butadiene of Chemical Formula 3 and the epoxy functional group of Chemical Formula 4 can be carried out as a first crosslinking bond for crosslinking reaction. Preferably, the chemical formula of the first crosslinking group R₆″ is Chemical Formula 4, the steric group of the molecule of Chemical Formula 4 is small, thereby the crosslinking reaction is easily carried out, the crosslinking efficiency is high, and the conditions are easily controlled. However, when Chemical Formula 3 is used as the first crosslinking group, the temperature required for the crosslinking reaction is high. When Chemical Formula 2 is used as the first crosslinking group, there is a small amount of reversible reaction, and the efficiency is reduced. Therefore, Chemical Formula 4 is a preferred first crosslinking group.

It should be noted that, in the present embodiment, the first crosslinking group R₆″ of the first polymer has low reactivity for self-crosslinking, and as a side chain of the first polymer, the first crosslinking group R₆″ is limited by the main chain and has weak movement ability, thereby the first crosslinking group R₆″ rarely undergoes a self-crosslinking reaction, and mainly undergoes a crosslinking reaction with the second crosslinking group.

In one embodiment, when the chemical formula of the first crosslinking group R₆″ is Chemical Formula 2, the second crosslinking groups R₈″ and R₁₀″ are each independently selected from any one of the following groups:

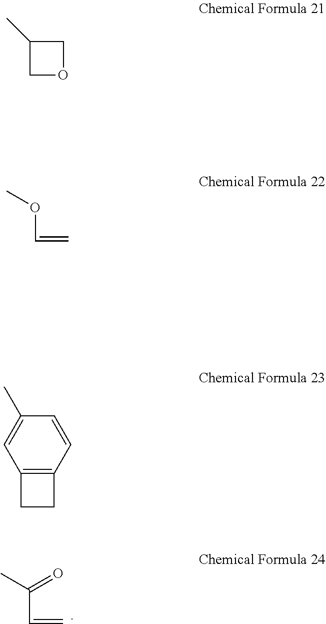

It should be understood that when the chemical formula of the first crosslinking group R₆″ is Chemical Formula 2, the second crosslinking groups R₈″ and R₁₀″ may be same groups or different groups. For example, the chemical formula of R₈″ and R₁₀″ may be both Chemical Formula 21, or both Chemical Formula 22, or both Chemical Formula 23, or both Chemical Formula 24. For another example, the chemical formula of R₈″ may be formula 21, and chemical formula of R₁₀″ may be formula 22, formula 23, or formula 24, that is R₈″ and R₁₀″ are different second crosslinking groups. It can be understood that when both R₈″ and R₁₀″ are formula 23, both the first crosslinking group R₆″ and the second crosslinking group R₈″ and R₁₀″ are phenylcyclohexane, that is, the phenylcyclohexanes in the first polymer and the crosslinking compound in the present embodiment can undergo a self-crosslinking reaction with each other. When the second crosslinking groups R₈″ and R₁₀″ are each independently selected from Chemical Formula 21, Chemical Formula 22 or Chemical Formula 24, the first crosslinking group R₆″ may undergo a crosslinking reaction with an epoxy or a double bond in the second crosslinking group to form a network-like cross-linked structure inside the hole transport thin film 10, thereby the solvent resistance of the hole transport thin film 10 is improved to better prevent the material component of the light-emitting layer from penetrating into the hole transport thin film 10.

In one embodiment, when the chemical formula of the first crosslinking group R₆″ is Chemical Formula 3, the second crosslinking groups R₈″ and R₁₀″ are each independently selected from any one of the following groups:

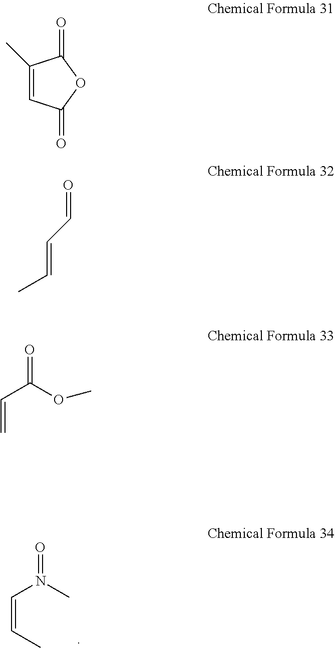

It should be understood that when the chemical formula of the first crosslinking group R₆″ is Chemical Formula 3, the second crosslinking groups R₈″ and R₁₀″ may be same groups or different groups. For example, the chemical formula of R₈″ and R₁₀″ may be both Chemical Formula 31, or both Chemical Formula 32, or both Chemical Formula 33, or both Chemical Formula 34. For another example, the chemical formula of R₈″ may be formula 31, and chemical formula of R₁₀″ may be formula 32, formula 33 or formula 34, that is R₈″ and R₁₀″ are different second crosslinking groups. The double bond of butadiene of Chemical Formula 3 undergoes a crosslinking (addition) reaction with the second crosslinking group (Chemical Formulas 31-34) as the first crosslinking bond to form a network-like cross-linked structure, thereby the solvent resistance of the hole transport thin film 10 is improved to better prevent the material component of the light-emitting layer from penetrating into the hole transport thin film 10.

In one embodiment, when the chemical formula of the first crosslinking group R₆″ is Chemical Formula 4, the second crosslinking groups R₈″ and R₁₀″ are each independently selected from one of a primary amine group (Chemical Formula 41) and a secondary amine group (Chemical Formula 42):

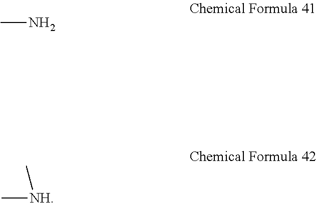

It should be understood that when the chemical formula of the first crosslinking group R₆″ is Chemical Formula 2, the second crosslinking groups R₈″ and R₁₀″ may be same groups or different groups. For example, R₈″ and R₁₀″ may be both the primary amine group, or both the secondary amine group. For another example, R₈″ is the primary amine group and R₁₀″ is the secondary amine group, or R₈″ is the secondary amine group and R₁₀″ is the primary amine group, that is R₈″ and R₁₀″ are different second crosslinking groups. Each of the epoxy functional groups in Chemical Formula 4 can be used as the first crosslinking bond to undergo a crosslinking reaction with a second crosslinking group (amino group) to form a network-like cross-linked structure, thereby the solvent resistance of the hole transport thin film 10 is improved to better prevent the material component of the light-emitting layer from penetrating into the hole transport thin film 10.

In one embodiment, a weight percentage of the crosslinking compound in the material of the hole transport thin film 10 is greater than 0 and less than or equal to 5%. The crosslinking compound has a non-conductive structure, it cannot play the role of hole transport, if the proportion of the crosslinking compound is too large, it will affect the hole transport efficiency. For example, when the weight percentage of the crosslinking compound is 50%, the maximum current efficiency of the device is only 10 cd/A. Therefore, when the weight percentage of the crosslinking compound is less than or equal to 5%, it is possible to ensure better hole transport efficiency, and at the same time, it is possible to form a network-like cross-linked structure to improve the solvent resistance of the hole transport thin film 10, so as to better prevent the material components of the light-emitting layer from penetrating into the hole transport thin film 10. At the same time, when the concentration of the crosslinking compound is low, correspondingly, the concentration of the second crosslinking group is also relatively low, which can greatly reduce the probability of self-crosslinking reaction of the second crosslinking group, so that the crosslinking reaction mainly occurs between the first crosslinking group and the second crosslinking group, and the effective utilization rate of the second crosslinking group is higher.

In one embodiment, in the material of the hole transport thin film 10, a weight average molecular weight of the first polymer is greater than or equal to 50,000 and less than or equal to 250,000. For example, the weight average molecular weight of the first polymer may be 50,000, 60,000, 70,000, 90,000, 120,000, 150,000, 180,000, 200,000, 250,000, etc. The degree of polymerization of the first polymer has a great influence on the interfacial mutual dissolution of the materials. When the weight average molecular weight of the first polymer is small, the hole transport thin film 10 may be interfacially mutually dissolved with the light-emitting layer, and when the weight average molecular weight of the first polymer is too large, the dissolution and dispersibility of the first polymer may be affected. Therefore, when the weight average molecular weight of the first polymer satisfies the above conditions, it is possible to better prevent the material component of the light-emitting layer from penetrating into the hole transport thin film 10, and the first polymer has good solubility.

In a fourth embodiment of the present disclosure, the first polymer is a block copolymer formed by a fluorene-containing group and a triphenylamine-containing group.

The hole transport thin film 10 further includes a fourth polymer which is a block copolymer formed by a fluorene-containing group, a triphenylamine-containing group, and a second self-crosslinking group. Hydrogen atoms in the fourth polymer are wholly or partially substituted with fluorine atoms.

It should be noted that the highest occupied molecular orbital (HOMO) energy level of the hole transport thin film 10 of the present embodiment is determined by the fluorene-containing group and the triphenylamine-containing group. When the mole fraction of the triphenylamine-containing group approaches 100%, the HOMO energy level of the hole transport thin film 10 approaches the HOMO energy level of polytriphenylamine (−4.8 eV). When the mole fraction of the triphenylamine-containing unit is 0%, the HOMO energy level of the hole transport thin film 10 approaches the HOMO energy level of the polyfluorene (−5.8 eV). Therefore, the HOMO energy level of the hole transport thin film 10 of the present embodiment can be in a range from −5.8 eV to −4.8 eV, which is located between the HOMO energy level of the hole injection layer and the HOMO energy level of the light-emitting layer, thereby the requirement that the hole injection layer injects holes into the light-emitting layer can be satisfied.

Moreover, in the process of manufacturing the material of the hole transport thin film 10 of the present embodiment into the hole transport thin film 10, the fourth polymer is more inclined to be located in the upper layer of the hole transport thin film 10 (referring to the structure of FIG. 1) due to the presence of fluorine atoms. This is because the fluorine atom has a large electronegativity, a small atomic radius, a short C—F bond, and a bond energy as high as 500 KJ/mol. The mutual repulsion of adjacent fluorine atoms causes the fluorine atoms not to be in a same plane, but to be spirally distributed along the carbon chain. Especially in a perfluorocarbon chain, the sum of the van der Waals radii of two fluorine atoms is about 0.27 nm, basically surrounding and filling the C—C—C bond. The almost void-free space barrier prevents any atoms or groups from entering and destroying the C—C bond. Therefore, during the film formation process, fluorine-containing groups tend to be enriched at the interface between the hole transport thin film 10 and the air (a side of the hole transport thin film 10 close to a light-emitting layer), and extend into the air. The closer to the top layer, the greater the content of the fourth polymer. At the same time, since the fourth polymer further includes the second self-crosslinking group, crosslinking reaction may occurs between the block copolymer molecules of the fourth polymer when the hole transport thin film 10 is formed, so that the upper layer of the hole transport thin film 10 (a layer close to the light-emitting layer) mainly includes cross-linked polymer. The cross-linked polymer has better solvent resistance, can prevent the material components of the light-emitting layer from penetrating into the hole transport thin film 10, and can reduce the interfacial mutual dissolution between the hole transport thin film 10 and the light-emitting layer, so as to improve the current efficiency of the device.

As an example, the content of the fourth polymer increases or decreases from one surface to another surface side of the hole transport thin film 10. For example, taking the photoelectric device shown in FIG. 1 as an example, the hole transport thin film 10 can be formed by a wet process, and during the wet process of film formation, fourth polymers tend to be enriched on the surface of the hole transport thin film 10 (i.e., the surface of the hole transport thin film 10 close to the light-emitting layer) due to the fluorine-containing group. Thereby the hole transport thin film 10 can form a gradual cross-linked structure from the bottom layer (a layer of the hole transport thin film 10 close to the hole injection layer) to the top layer (a layer of the hole transport thin film 10 close to the light-emitting layer). The closer to the bottom layer, the higher the content of the first polymer, that is, the layer of the hole transport thin film 10 close to the hole injection layer mainly has a non-cross-linked structure. The closer to the top layer, the higher the content of the fourth polymer, and the cross-linked structure formed by the second self-crosslinking group in the fourth polymer can prevent the material component of the light-emitting layer from penetrating into the hole transport thin film 10, thereby reducing the interfacial mutual dissolution between the hole transport thin film 10 and the light-emitting layer, thereby improving the current efficiency of the photoelectric device.

In one embodiment, the material of the hole transport thin film 10 is a composition of a first polymer and a fourth polymer. The first polymer is a block copolymer formed by a fluorene-containing group and a triphenylamine-containing group. The fourth polymer is a block copolymer formed by a fluorene-containing group, a triphenylamine-containing group, and a second self-crosslinking group. Hydrogen atoms in the fourth polymer are wholly or partially substituted with fluorine atoms. That is, the material of the hole transport thin film 10 is only the first polymer and the fourth polymer. It can be understood that, in addition to the first polymer and the fourth polymer, the material of the hole transport thin film 10 may further include other materials, such as a high thermal conductivity material to enhance the heat dissipation of the hole transport thin film 10, or a magnetic material to enhance the magnetic properties of the hole transport thin film 10.

When the material of the hole transport thin film 10 includes only the first polymer and the fourth polymer, it is preferable that the weight percentage of the fourth polymer in the material of the hole transport thin film 10 is greater than or equal to 5% and less than or equal to 40%. That is, the weight percentages of the fourth polymer may be 5% and the weight percentages of the first polymer may be 95%, or the weight percentages of the fourth polymer may be 10% and the weight percentages of the first polymer may be 90%, or the weight percentages of the fourth polymer may be 15% and the weight percentages of the first polymer may be 85%, or the weight percentages of the fourth polymer may be 22% and the weight percentages of the first polymer may be 78%, or the weight percentages of the fourth polymer may be 29% and the weight percentages of the first polymer may be 71%, or the weight percentages of the fourth polymer may be 35% and the weight percentages of the first polymer may be 65%, or the weight percentages of the fourth polymer may be 40% and the weight percentages of the first polymer may be 60%, and the like. Since the fourth polymer contains self-crosslinking group, if the weight percentage of the fourth polymer is too large, on the one hand, the large proportion of non-hole transport component affects the hole transport efficiency, and on the other hand, excessive crosslinking will also lead to a decrease in hole transport efficiency. Therefore, the weight percentage of the fourth polymer is preferably 5%˜40%.

In one embodiment, a structural formula of the first polymer in the hole transport thin film 10 is as following:

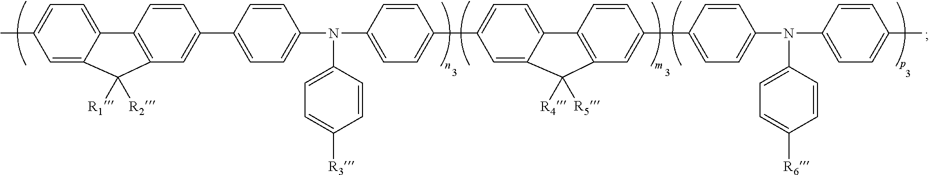

where n₃, m₃, and p₃ are molar fractions, n₃+m₃+p₃=1, 0<n₃<1, 0≤m₃<1, 0≤p₃<1; R₁′″ to R₆′″ are same groups or different groups; and R₁′″ to R₆′″ are independently selected from a C₁-C₂₀ alkyl, an aromatic group, or a heteroaromatic group.

It can be understood that R₁′″ to R₆′″ may be same substituents, for example, they can be alkyls, aromatic groups, or heteroaromatic groups at the same time. R₁′″ to R₆′″ may also be different substituents from each other. For convenience of description, a copolymerized repeating unit formed by the fluorene-containing group and the triphenylamine-containing group is referred to as a unit A′, a homopolymerized repeating unit formed by the fluorene-containing group is referred to as a unit B′, and a homopolymerized repeating unit formed by the triphenylamine-containing group is referred to as a unit C′. It can be understood that the first polymer of the present embodiment may include the unit A′, or may be a block copolymer including the unit A′ and the unit B′, or may be a block copolymer including the unit A′ and the unit C′, or may be a block copolymer including the unit A′, the unit B′ and the unit C′ at the same time, which is not particularly limited in the embodiment of the present disclosure. The molar fraction of the triphenylamine-containing group may be determined according to the needs of HOMO energy level, and then the corresponding polymer structure may be selected.

In one embodiment, a structural formula of the fourth polymer in the hole transport thin film 10 is as following:

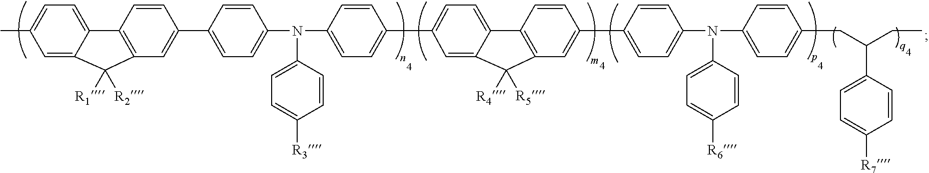

where n₄, m₄, p₄, and q₄ are molar fractions, n₄+m₄+p₄+q₄=1, 0<n₄<0.95, 0≤m₄<0.95, 0≤p₄<0.95, 0<p₄<0.05; R₁″″ to R₆″″ are same groups or different groups, and R₁″″ to R₆″″ are independently selected from a C₁-C₂₀ alkyl, an aromatic group, or a heteroaromatic group; R₇″″ contains a crosslinking bond.

It should be noted that R₁″″ to R₆″″ may be same groups as R₁′″ to R₆′″ and can make the same selection as the above R₁′″ to R₆′″, and R₁″″ to R₆″″ may also be different groups independent of R₁′″ to R₆′″. For convenience of description, a copolymerized repeating unit formed by the fluorene-containing group and the triphenylamine-containing group is referred to as a unit A″, a homopolymerized repeating unit formed by the fluorene-containing group is referred to as a unit B″, a homopolymerized repeating unit formed by the triphenylamine-containing group is referred to as a unit C″, and a homopolymerized repeating unit formed by the self-crosslinking group is referred to as a unit D″. It can be understood that the fourth polymer of the present embodiment may include only the unit A″ and the unit D″, or may be a block copolymer including the unit A′, the unit D″ and the unit B′, or may be a block copolymer including the unit A″, the unit D″ and the unit C″, or may be a block copolymer including the unit A″, the unit D″, the unit B″ and the unit C″ at the same time, which is not particularly limited in the embodiment of the present disclosure. The molar fraction of the unit A″ and the unit D″ may be determined according to the needs of HOMO energy level, and then the corresponding polymer structure may be selected.

It should be noted that, in the present embodiment, if the molar fraction ratio of the unit D″ is too high, it may lead to excessive crosslinking in the polymer, which may affect the conductivity of the material, and thus reduce the hole mobility. Therefore, it is preferable that the mole fraction of the second self-crosslinking group unit D″, is greater than 0 and less than or equal to 5%, thatis, 0<q₄/(n₄+m₄+p₄+q₄)≤0.05, so that the crosslinking polymer can be formed to prevent the material of the light-emitting layer from penetrating into the hole transport thin film 10 without reducing the hole mobility of the hole transport thin film 10.

It can be understood that the substituent R₇″″ in the second self-crosslinking group unit D″ may be a group containing a thermal crosslinking bond and the crosslinking reaction is carried out by heating, or a group containing a crosslinking bond responsive to ultraviolet light and the crosslinking reaction is carried out by irradiation with ultraviolet light.

In some embodiments, the second self-crosslinking group may be a double bond or a group that can form a double bond when reactive when reactive. A cross-linked structure can be formed between molecules of the fourth polymer through an addition reaction of the double bond. For example, R₇″″ of the fourth polymer may be one of the following structural formulas:

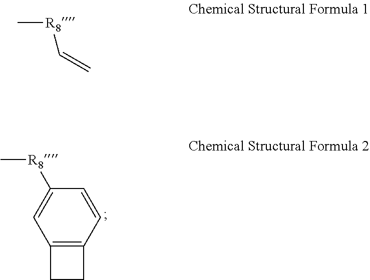

where R₈″″ is a C₁-C₂₀ alkyl; or R₈″″ is a C₁-C₂₀ alkyl, and one or more carbon atoms are substituted with heteroatoms, when a plurality of carbon atoms are substituted with heteroatoms, the heteroatoms are located in a non-adjacent position to allow the above substituents to have better flexibility. In the above R₇″″ group, the double bond in Chemical Structural Formula 1 may undergo an addition reaction to form a cross-linked structure between fourth polymers. The molecular structure of Chemical Structural Formula 2 will be isomerized when heated, and the reaction formula is as following:

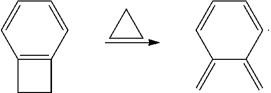

After isomerization, two double bonds are formed, and a crosslinking reaction can be carried out between the fourth polymers to obtain a cross-linked polymer. The cross-linked structure has better solvent resistance and can prevent small molecules in the light-emitting layer from infiltrating into the hole transport thin film 10 (that is interfacial mutual dissolution), thereby improving the hole mobility and the stability of the photoelectric device.

It should be noted that due to the complexity of polymer chemical reactions, the above-described crosslinking reaction may not necessarily proceed 100% according to an ideal crosslinking reaction model, but at least a certain proportion of cross-linked structures can be formed.

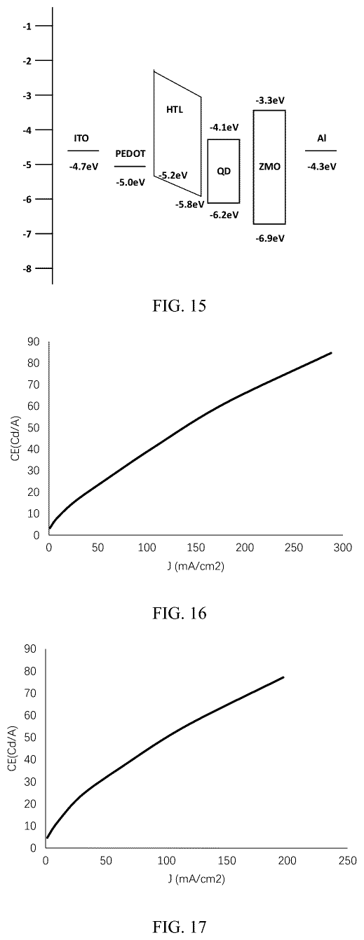

In one embodiment, the mole fraction of the triphenylamine-containing group in the fourth polymer is less than the mole fraction of the triphenylamine-containing group in the first polymer. It should be noted that the higher the content of triphenylamine-containing groups in a polymer, the higher the HOMO energy level of the polymer. The hole transport thin film 10 of the present embodiment forms a gradient molecular structure from the bottom layer (a layer of the hole transport thin film 10 close to the hole injection layer) to the top layer (a layer of the hole transport thin film 10 close to the light-emitting layer). The closer to the top layer, the greater the content of the fourth polymer, and the closer to the bottom layer, the greater the content of the first polymer. Therefore, when the mole fraction of the triphenylamine-containing group in the fourth polymer is smaller than the mole fraction of the triphenylamine-containing group in the first polymer, the hole transport thin film 10 may form a gradient energy level structure from the high HOMO energy level of the bottom layer to the low HOMO energy level of the top layer. Referring to FIG. 15, FIG. 15 is a schematic diagram of HOMO energy level matching of each functional layer provided by the embodiment of the present disclosure, the hole transport thin film 10 forms a gradient HOMO energy level from −5.2 eV (the bottom layer of the hole transport thin film 10) to −5.8 eV (the top layer of the hole transport thin film 10), and the HOMO energy level of the bottom layer of the hole transport thin film 10 is close to the HOMO energy level of the hole transport layer (HJL), so that the injection efficiency of holes from the hole injection layer to the hole transport thin film 10 can be improved. The HOMO energy level of the top layer of the hole transport thin film 10 is close to the HOMO energy level of the light-emitting layer, thereby reducing the energy level difference between the hole transport thin film 10 and the light-emitting layer, making it easier for holes to cross the potential barrier from the hole transport thin film 10 to the light-emitting layer, and thus the hole mobility can be improved. Moreover, the layer of the hole transport thin film 10 close to the light-emitting layer mainly includes cross-linked polymers, which has better solvent resistance and can prevent the material components of the light-emitting layer from penetrating into the hole transport thin film 10, thereby reducing the interfacial mutual dissolution between the hole transport thin film 10 and the light-emitting layer to improve the current efficiency.

The hole transport thin film 10 of the present embodiment can not only improve the hole mobility, but also reduce the occurrence of interfacial mutual dissolution between the hole transport thin film 10 and the light-emitting layer, so as to improve the current efficiency.

In the fifth embodiment of the present disclosure, the first polymer further includes a heteroaryl-containing group, in other words, the first polymer includes a fluorene-containing group, an aniline-containing group, and a heteroaryl-containing group.

A weight average molecular weight of the first polymer ranges from 60,000 to 150,000.

As used in the present disclosure, the “heteroaryl” means that one or more carbon atoms in an aryl are independently replaced by one or more heteroatoms (e.g., N, O, P, and/or S). For example, the heteroaryl has 3 to 20 carbon atoms, or 5 to 15 carbon atoms, or 5 to 9 carbon atoms. The heteroaryl may be unsubstituted, or may have one or more hydrogen atoms thereon optionally substituted with other groups, for example, alkyl, halogen, etc., and multiple degrees of substitution is allowed. In some embodiments of the present disclosure, the heteroaryl may be, for example, thienyl or carbazolyl.

If the weight average molecular weight of the first polymer is too high or too low, the degree of improvement of the optoelectronic performance of the photoelectric device is limited. If the weight average molecular weight of the first polymer is less than 60,000, the degree of crosslinking of the film is limited, thus the degree of improvement of the anti-solvent properties of the film is limited. If the weight average molecular weight of the first polymer is higher than 150,000, the viscosity of the first polymer solution prepared by dispersing the first polymer in a solvent is too high, which is not conducive to construction, so that that film-forming quality is decreased. For example, if the film is prepared by an inkjet printing method, the inkjet printing apparatus may not be compatible with the first polymer solution having an excessively high viscosity.

The hole transport thin film 10 can be used to prepare a hole functional layer of a photoelectric device, such as a hole transport layer. Taking the photoelectric device QLED as an example, since the quantum dots of the material of the light-emitting layer are inorganic nanoparticles, the quantum dots have good dissolution characteristics and stability in solvent (such as ethanol) after ligand modification. The light-emitting layer prepared by solution method has the advantages of no vacuum process, easy realization of large area, and low cost, so the light-emitting layer is usually prepared by solution method. For a QLED with an upright structure, it is necessary to prepare a hole functional layer first, and then prepare a light-emitting layer. If both the hole functional layer and the light-emitting layer are prepared by the solution method, the hole functional layer and the light-emitting layer will be mutually dissolved, resulting in a decrease in the hole injection level. Moreover, QLED itself has the problem that the hole injection level is lower than the electron injection level, thereby the “mutual dissolution” phenomenon will aggravate the imbalance of carrier injection of QLED, thus leading to a decrease in the comprehensive performance of QLED. The thin film of the embodiment of the present disclosure has ideal anti-solvent characteristics, which effectively improves the phenomenon of “mutual solubility”, and is beneficial to improving the photoelectric performance of the photoelectric device.

In order to further improve the anti-solvent properties of the hole transport thin film 10, in some embodiments of the present disclosure, a glass transition temperature of the first polymer is 80° C. to 250° C. For example, the glass transition temperature of the first polymer may be 80° C. to 100° C., 100° C. to 120° C., 120° C. to 200° C., 200° C. to 220° C., or 220° C. to 250° C.

In order to further improve the anti-solvent properties of the hole transport thin film 10, in some embodiments of the present disclosure, a ratio of the weight average molecular weight to the number average molecular weight of the first polymer is not greater than 2. As used the present disclosure, “number average molecular weight” refers to the averaged molar weight value in a polymer is statistically by the number of molecules. The ratio of the weight average molecular weight to the number average molecular weight of the first polymer refers to the dispersion index of the first polymer, and is used to evaluate the molecular weight distribution of the first polymer, and the dispersion index of the first polymer is limited to achieve accurate control, thereby improving the repeatability and stability of the photoelectric device to which the thin film is applied.

In some embodiments of the present disclosure, the heteroaryl-containing group is selected from at least one of a carbazolyl-containing group or a thienyl-containing group.

In order to further improve the anti-solvent properties of the hole transport thin film 10 and to further achieve fine adjustment to ensure the repeatability and stability of the photoelectric device to which the thin film is applied, in some embodiments of the present disclosure, in the first polymer, more than 10% by weight of the polymer has a molecular weight of 0.9 to 1.1 times the weight average molecular weight of the first polymer. No more than 5% by weight of the polymer has a molecular weight less than 0.3 times the weight average molecular weight of the first polymer, or no more than 5% by weight of the polymer has a molecular weight greater than 1.7 times the weight average molecular weight of the first polymer.

In some embodiments of the present application, the repeating units of the first polymer are selected from the group consisting of:

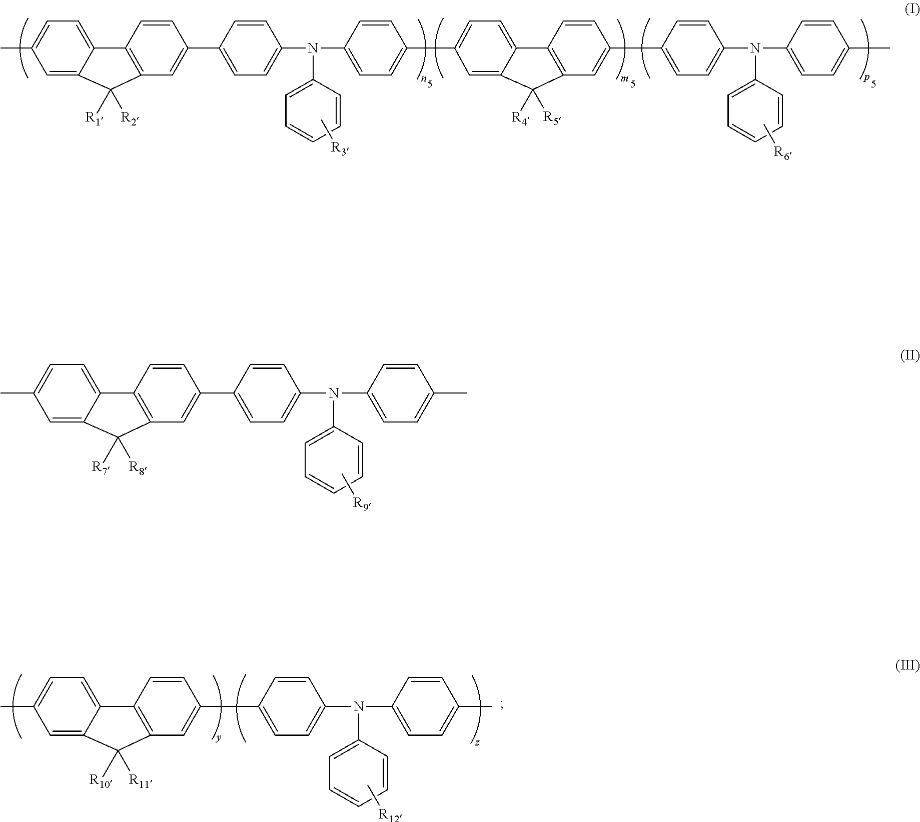

where R_{1′} to R_{20′} are independently selected from a hydrogen atom, an alkyl having 1 to 20 carbon atoms, an aryl, or a heteroaryl; n₅, m₅, p₅, y, and z respectively represent mole fractions;
In the structural formula (I), the sum of m₅, n₅ and p₅ is 1, 0.5<n₅<0.9, 0.1<m₅<0.4, and 0<p₅<0.1;
In structural formula (III), the sum of y and zis 1, 0<y<0.5, and 0.5<<1.

As used in the present disclosure, “alkyl” refers to a type of chain organic groups containing only carbon atoms and hydrogen atoms. The alkyl includes both unsubstituted alkyls and alkyls in which one or more hydrogen atoms are optionally substituted with other groups, which may for example be halogen atoms, and multiple degrees of substitution is allowed. The alkyl may for example be one or more of methyl, ethyl, n-propyl and isopropyl.

It should be understood that for a first type of the first polymers having same general formulas, those skilled in the art know how to obtain polymers with different degrees of polymerization by controlling the reaction conditions, for example by regulating the reaction time of the monomers.

An embodiment of the present disclosure further provides a method for preparing a photoelectric device. Referring to FIG. 2, FIG. 2 is a flowchart of a preparation method for a photoelectric device according to an embodiment of the present disclosure, and the method for preparing a photoelectric device includes the following steps:

Step S21: providing a material solution comprising a first polymer, wherein the first polymer includes a fluorene-containing group and an aniline-containing group.

In this step, the first polymer may first be prepared into a polymer solution, for example, the first polymer may be dissolved by a conventional organic solvent such as toluene, chlorobenzene, cyclohexylbenzene, methyl benzoate, ethyl benzoate, anisole, and the like. The solvent may be a single solvent, or may be a mixed solvent formed of two or more different kinds of solvents.

In this embodiment, the order in which the first polymer and the solvent are added is not limited, as long as sufficient mixing is achieved to obtain a polymer solution.

Step S22: providing a substrate on which an anode is formed, disposing the above-described material solution on the anode, and heating to obtain a hole transport thin film.

In this step, the type of the substrate is not limited. The substrate may be a conventionally used substrate, for example, a rigid substrate with a material of glass, or a flexible substrate with a material of polyimide. A material of the anode 40 may be, for example, one or more of a metal, a carbon material, and a metal oxide. The metal may be, for example, one or more of Al, Ag, Cu, Mo, Au, Ba, Ca, and Mg. The carbon material may be, for example, one or more of graphite, carbon nanotubes, graphene, and carbon fibers. The metal oxide may be a doped metal oxide or un-doped metal oxide, including one or more of ITO, FTO, ATO, AZO, GZO, IZO, MZO, and AMO. The anode 40 may also be a composite electrode with metal sandwiched between doped or un-doped transparent metal oxides. The composite electrode includes, but not limited to, one or more of AZO/Ag/AZO, AZO/Al/AZO, ITO/Ag/ITO, ITO/Ag/ITO, ZnO/Ag/ZnO, ZnO/Ag/ZnO, TiO₂/Ag/TiO₂, TiO₂/Ag/TiO₂, ZnS/Ag/ZnS, ZnS/Ag/ZnS, TiO₂/Ag/TiO₂, and TiO₂/Al/TiO₂. In one embodiment, an anode 40 is formed on the substrate, and a hole transport thin film 10 including the first polymer and the second polymer is disposed on the anode 40. In another embodiment, an anode 40 and a hole injection layer 50 are formed on the substrate, and a hole transport thin film 10 including the first polymer and the second polymer is disposed on the hole injection layer 50. If the photoelectric device further includes other functional layers, the other functional layers may also be formed on the substrate accordingly.

The first polymer in this embodiment can refer to the relevant description in the above embodiments, and will not be repeated here.

Specifically, the material solution including the first polymer may be disposed on the substrate by a solution method. The solution method may include, but not limited to, spin-coating, drop coating, coating, inkjet printing, blade coating, dip pulling, soaking, spray coating, roll coating, evaporation, casting, and the like. A wet film is prepared by the solution method, and then heat treatment to obtain the hole transport thin film 10.

In one embodiment, the step of heating includes: firstly, performing a first heat treatment, and then performing a second heat treatment. The temperature of the first heat treatment is greater than or equal to 40° C. and less than 100° C. The temperature of the second heat treatment is greater than or equal to 100° C. and less than or equal to 250° C.

During the step of heating, the wet film on the substrate may first be subjected to the first heat treatment to volatilize the organic solvent in the wet film to form a hole transport thin film, and then the hole transport thin film may be subjected to the second heat treatment. The temperature of the second heat treatment is greater than that of the first heat treatment. The second heat treatment is configured to eliminate the residual stress inside the hole transport thin film, thereby reducing the risk of layer deformation and cracks in the hole transport thin film. For example, the temperature of the first heat treatment may be less than 100° C., such as 95° C., 80° C., 70° C., 60° C., 50° C., 40° C., and the like. The higher the temperature of the first heat treatment, the faster the wet film dries. The wet film may also be vacuum dried at room temperature. The temperature of the second heat treatment may be between 100° C. and 250° C., for example, the temperature of the second heat treatment may be 100° C., 130° C., 160° C., 180° C., 200° C., 220° C., 240° C., 250° C., and the like. It can be understood that the second heat treatment may be an annealing process including a sequential heating, heat preservation and cooling process. For example, the dried hole transport thin film is heated to 220° C. and keep for 30 minutes, and then cooled to room temperature at a rate of 5° C./min.

In the present embodiment, it is possible to control and adjust the thickness of the finally formed hole transport thin film by controlling and adjusting conditions such as the concentration of the solution used in the solution method. The thickness of the hole transport thin film may range from 10 nm to 50 nm, such as 10 nm, 15 nm, 20 nm, 25 nm, 30 nm, 40 nm, 50 nm, and the like. Taking spin-coating as an example, the thickness of the hole transport thin film can be controlled by adjusting the concentration of the solution, the spin-coating speed, and the spin-coating time.

Step S23: forming a cathode on the hole transport thin film.

A material of the cathode 20 is a material known in the art for cathode. The material of the cathode 20 can be selected from the material of the anode 40 described above, which will not be repeated here. The thickness of the cathode 20 is a cathode thickness known in the art, for example, the thickness of the cathode 20 may range from 10 nm to 200 nm, such as 10 nm, 35 nm, 50 nm, 80 nm, 120 nm, 150 nm, 200 nm, and the like.

It should be noted that, in the present disclosure, the anode 40, the light-emitting layer 30, the cathode 20 and other functional layers can all be prepared by conventional techniques in the art, which include but not limited to solution method and deposition method. The solution method includes but are not limited to spin-coating, coating, inkjet printing, blade coating, dip pulling, soaking, spray coating, roller coating or casting. The deposition method includes chemical method and physical method. The chemical method includes but are not limited to chemical vapor deposition, continuous ion layer adsorption and reaction method, anodizing method, electrolytic deposition method, or co-precipitation method. The physical method includes but not limited to thermal evaporation coating method, electron beam evaporation coating method, magnetron sputtering method, multi-arc ion coating method, physical vapor deposition method, atomic layer deposition, or pulsed laser deposition. When the anode 40, the light-emitting layer 30, the cathode 20 and other functional layers are prepared using the solution method, a drying process needs to be added.

It should be understood that, the method for preparing a photoelectric device may further include an encapsulation step. An encapsulation material for encapsulation may be acrylic resin or epoxy resin. The encapsulation may be machine encapsulation or manual encapsulation. The encapsulation may adopt ultraviolet curing glue sealing. Concentrations of oxygen and water in the environment where the encapsulation step is performed are both lower than 0.1 ppm to ensure the stability of the photoelectric device.

In some embodiments of the present disclosure, the material solution including the first polymer is further added with a second polymer, wherein the second polymer is a block copolymer formed by a fluorene-containing group and a triphenylamine-containing group. A mole fraction of the triphenylamine-containing group in the second polymer is less than a mole fraction of the triphenylamine-containing group in the first polymer, and the hydrogen atoms in the second polymer are wholly or partially substituted with fluorine atoms.

The second polymer is more inclined to be located in the upper layer of the hole transport thin film 10 (referring to the structure of FIG. 1) due to the presence of fluorine atoms, thereby the hole transport thin film 10 forms a gradient molecular structure from the bottom layer to the top layer. The closer to the top layer, the greater the content of the second polymer, and the closer to the bottom layer, the greater the content of the first polymer. That is the content of the second polymer increases from the surface of the hole transport thin film 10 facing the anode to the surface of the hole transport thin film 10 away from the anode.

It can be understood that when the second polymer is further added to the material solution including the first polymer, in the present embodiment, in the process of preparing the material solution including the first polymer, the order of adding the first polymer, the second polymer, and the solvent is not limited, as long as the polymer solution can be obtained by sufficiently mixing the first polymer, the second polymer, and the solvent.

The second polymer in this embodiment can refer to the relevant description in the above embodiments, and will not be repeated herein.

In the present embodiment, the material solution in which the first polymer and the second polymer are dissolved is disposed on the anode 40 of the substrate to form a hole transport thin film, during the film formation process, second polymers including the fluorene-containing groups tend to be enriched at the interface between the hole transport thin film 10 and air (a side of the hole transport thin film 10 close to the cathode), and extend into the air, so that the hole transport thin film 10 forms a gradient molecular structure from the bottom layer (a layer of the hole transport thin film 10 close to the anode) to the top layer (a layer of the hole transport thin film 10 close to the cathode). The closer to the top layer, the greater the content of the second polymer, and the closer to the bottom layer, the greater the content of the first polymer. There are relatively more aniline-containing groups in the first polymer and relatively few aniline-containing groups in the second polymer, thereby the HOMO energy level of the first polymer is higher, and the HOMO energy level of the second polymer is lower. Corresponding to the gradient molecular structure of the thin film from the bottom layer to the top layer, the hole transport thin film 10 forms a gradient energy level from high to low from the bottom layer to the top layer. The high HOMO energy level of the bottom layer matches the anode, which facilitates the anode to inject holes into the hole transport thin film 10. The low HOMO energy level of the top layer reduces the energy level difference between the hole transport thin film 10 and the light-emitting layer, making it easier for holes to overcome the potential barrier between the hole transport thin film 10 and the light-emitting layer and transition to the light-emitting layer. Therefore, the hole transport thin film 10 of the embodiment of the present disclosure can improve the hole mobility, and thus can improve the current efficiency of corresponding photoelectric devices. In addition, since the first polymer and the second polymer contained in the hole transport thin film 10 of the embodiment of the present disclosure are the same type of polymer material, and the inside of the thin film has a gradient molecular structure which is not a traditional double-layer transport thin film, thereby there is no interfacial mutual dissolution problems between material interface and between different transport thin film layers. Therefore, the hole transport thin film 10 prepared by the embodiment of the present disclosure can be improved with hole mobility, and there is no problem of interfacial mutual dissolution.

In another embodiments of the present disclosure, the first polymer is a block polymer including a first block and a second block. The first block is a copolymerized block formed by a fluorene-containing group and an aniline-containing group. The second block is a copolymerized block formed by a fluorene-containing group and an aniline-containing group, and the aniline-containing group in the second block is connected with an electron-donating group. At this time, the material solution including the first polymer may further include a third polymer, and the third polymer may be a conductive polymer.

It can be understood that when the third polymer is further added to the material solution including the first polymer, in the present embodiment, during the preparation of the material solution including the first polymer, the order of adding the first polymer, the third polymer, and the solvent is not limited, as long as the polymer solution can be obtained by sufficiently mixing the first polymer, the third polymer, and the solvent.

When the first polymer does not include a first self-crosslinking group, the wet film on the substrate may first be subjected to a first heat treatment to have the organic solvent in the wet film volatilized to form a hole transport thin film, and then the hole transport thin film may be subjected to a second heat treatment.

When the first polymer includes the first self-crosslinking group, the drying treatment may be a step of simultaneously including crosslinking and curing. For example, if the first self-crosslinking group in the first polymer contains a thermally crosslinking bond, a crosslinking treatment may be performed by heating. For example, the wet film on the substrate may first be subjected to a first heat treatment to volatilize the organic solvent in the wet film to form a molten hole transport thin film, and then the hole transport thin film may be subjected to a second heat treatment to have first polymer cross-linked and cured. The temperature of the second heat treatment is higher than the temperature of the first heat treatment, for details, reference may be made to the above contents. For another example, if the first self-crosslinking group in the first polymer contains a crosslinking bond group responsive to ultraviolet light, the crosslinking reaction can be carried out by irradiation with ultraviolet light, for example, the first heat treatment process described above is used to volatilize the organic solvent to form a molten hole transport thin film, and then the thin film is irradiated with ultraviolet light having a wavelength of 365 nm to have the hole transport thin film cross-linked and cured.

The first polymer and the third polymer in this embodiment can refer to the relevant description in the above embodiments, and will not be repeated herein.

In the present embodiment, in the process of preparing the material solution including the first polymer, the order of adding the first polymer, the third polymer, and the solvent is not limited, as long as the block copolymer solution can be obtained by sufficiently mixing the first polymer, the third polymer, and the solvent.

In the present embodiment, the material solution in which the first polymer and the third polymer are dissolved is disposed on the substrate to form a hole transport thin film, during the film formation process, first polymers including fluorene-containing groups tend to be enriched at the interface between the hole transport thin film 10 and air (a side of the hole transport thin film 10 close to the light-emitting layer), and extend into the air, so that the hole transport thin film 10 forms a gradient molecular structure from the bottom layer (a layer of the hole transport thin film 10 close to the hole injection layer) to the top layer (a layer of the hole transport thin film 10 close to the light-emitting layer). The closer to the bottom layer, the greater the content of the third polymer, and the closer to the top layer, the greater the content of the first polymer. The first polymer mainly located in the top layer contains the electron-donating group, thereby the LUMO energy level of the top layer of the hole transport thin film 10 can be improved. Corresponding to the gradient molecular structure from the bottom layer to the top layer, the hole transport thin film 10 can form a gradient LUMO energy level that gradually increases from the bottom layer to the top layer. The increase of LUMO energy level in the top layer of the hole transport thin film 10 increases the difficulty of electron transition from the light-emitting layer to the hole transport layer, which can reduce the aging rate of the hole transport layer and improve the lifetime of the photoelectric device.

In yet another embodiment, the first polymer includes a fluorene-containing group, an aniline-containing group, and a group containing a first crosslinking group. The material solution including the first polymer further includes a crosslinking compound. The crosslinking compound includes a main chain, and at least two second crosslinking groups connected to the main chain. The hydrogen atoms in the crosslinking compound are wholly or partially substituted with fluorine atoms.

In the present embodiment, in the process of preparing the material solution including the first polymer, the order of adding the first polymer, the crosslinking compound, and the solvent is not limited, as long as the block copolymer solution can be obtained by sufficiently mixing the first polymer, the crosslinking compound, and the solvent.

The first polymer and the crosslinking compound in this embodiment can refer to the relevant description in the above embodiments, and will not be repeated herein.

In this embodiment, the material solution in which the first polymer and the crosslinking compound are dissolved is disposed on a substrate to form a hole transport thin film, and during the film formation process, the second crosslinking group in the crosslinking compound can undergo a crosslinking reaction with the first crosslinking group in the first polymer. The crosslinking compound contains at least two second crosslinking groups and the first polymer contains one first crosslinking group, thereby the crosslinking compound can connect at least two first polymer molecules to form a cross-linked structure in the hole transport thin film 10. At the same time, due to the presence of fluorine atoms in the crosslinking compound, crosslinking compounds tend to be enriched at the upper layer of the hole transport thin film 10 (referring to the structure of FIG. 1), that is, fluorine-containing groups tend to be enriched at the interface between the hole transport thin film 10 and air (a side of the hole transport thin film 10 close to the light-emitting layer) during the film formation process, so that the hole transport thin film 10 forms a gradient molecular structure from the bottom layer (a layer of the hole transport thin film 10 close to the hole injection layer) to the top layer (a layer of the hole transport thin film 10 close to the light-emitting layer). The closer to the bottom layer, the greater the content of the first polymer, that is, the layer of the hole transport thin film 10 close to the hole injection layer includes mainly non-cross-linked structure. The closer to the top layer, the greater the content of the crosslinking compound, thereby the content of the cross-linked structure is also more, that is, the surface of the hole transport thin film 10 close to the light-emitting layer mainly includes the cross-linked structure. The cross-linked structure has good solvent resistance, thereby it is possible to prevent the material component of the light-emitting layer from penetrating into the hole transport thin film 10. Therefore, the hole transport thin film 10 prepared by the embodiment of the present disclosure can reduce the occurrence of interfacial mutual dissolution between the hole transport thin film 10 and the light-emitting layer, thereby improving the current efficiency of the photoelectric device.

In yet another embodiment, the first polymer is a block copolymer formed by a fluorene-containing group and a triphenylamine-containing group. The material solution including the first polymer further includes a fourth polymer. The fourth polymer is a block copolymer formed by a fluorene-containing group, a triphenylamine-containing group, and a second self-crosslinking group, and hydrogen atoms in the fourth polymer are wholly or partially substituted with fluorine atoms.

In the present embodiment, in the process of preparing the material solution including the first polymer, the order of adding the first polymer, the fourth polymer, and the solvent is not limited, as long as a polymer solution can be obtained by sufficiently mixing the first polymer, the fourth polymer, and the solvent.

The first polymer and the fourth polymer in this embodiment can refer to the relevant description in the above embodiments, and will not be repeated herein.

In one embodiment, when the second self-crosslinking group in the fourth polymer contains a thermally crosslinking bond, a crosslinking treatment may be performed by heating. For example, the wet film on the substrate may first be subjected to a first heat treatment to volatilize the organic solvent in the wet film to form a molten hole transport thin film, and then the hole transport thin film may be subjected to a second heat treatment to have fourth polymer cross-linked and cured. The temperature of the second heat treatment is higher than the temperature of the first heat treatment. For example, the temperature of the first heat treatment may be less than 100° C., such as 95° C., 80° C., 70° C., 60° C., 50° C., 40° C., and the like. The higher the temperature of the first heat treatment, the faster the solvent evaporates. The wet film may also be vacuum dried at room temperature. The temperature of the second heat treatment may range from 100° C. to 200° C., for example, the temperature of the second heat treatment may be 100° C., 120° C., 140° C., 160° C., 180° C., 190° C., 200° C., and the like.

In one embodiment, if the second self-crosslinking group in the fourth polymer contains a crosslinking bond group responsive to ultraviolet light, the crosslinking reaction can be carried out by irradiation with ultraviolet light, for example, the first heat treatment process described above is used to volatilize the organic solvent to form a molten hole transport thin film, and then the thin film is irradiated with ultraviolet light having a wavelength of 365 nm to have the hole transport thin film cross-linked and cured.

In this embodiment, a material solution in which the first polymer and the fourth polymer are dissolved is disposed on a substrate, and then a crosslinking reaction is performed to obtain a hole transport thin film 10. The HOMO energy level of the hole transport thin film 10 can be in a range from −5.8 eV to −4.8 eV, which is located between the HOMO energy level of the hole injection layer and the HOMO energy level of the light-emitting layer, thereby the requirement that the hole injection layer injects holes into the light-emitting layer can be satisfied. Furthermore, during the film formation process, due to the presence of fluorine atoms, fourth polymers tend to be enriched at the interface between the hole transport thin film 10 and the air (a side of the hole transport thin film 10 close to a light-emitting layer), and extends into the air, thereby the hole transport thin film 10 forms a gradient molecular structure from the bottom layer to the top layer. The closer to the top layer, the greater the content of the fourth polymer, and the closer to the bottom layer, the greater the content of the first polymer. At the same time, since the fourth polymer further includes the second self-crosslinking group, crosslinking reaction may occur between the block copolymer molecules of the fourth polymer when the hole transport thin film 10 is formed, so that the layer of the hole transport thin film 10 close to the light-emitting layer mainly includes cross-linked polymer. The cross-linked polymer has better solvent resistance, can prevent the material components of the light-emitting layer from penetrating into the hole transport thin film 10, and can reduce the interfacial mutual dissolution between the hole transport thin film 10 and the light-emitting layer, so as to improve the current efficiency of the device.

In yet another embodiment, the first polymer includes a fluorene-containing group, an aniline-containing group, and a heteroaryl-containing group.

The solvent may be selected from, but is not limited to, one or more of chlorobenzene, toluene, xylene, cyclohexylbenzene, methyl benzoate, ethyl benzoate, chloronaphthalene, phthalic anhydride, and bromobenzene.

Referring to FIG. 1, an embodiment of the present disclosure further provides a photoelectric device 100. The photoelectric device 100 includes a cathode 20, a light-emitting layer 30 and an anode 40 stacked in sequence. The photoelectric device 100 further includes the above-described hole transport thin film 10 located between the light-emitting layer 30 and the anode 40. The hole transport thin film 10 includes a first surface and a second surface, wherein the first surface faces the anode 40, and the second surface faces the light-emitting layer 30.

The material of the cathode 20 is a material known in the art for use in the cathode, and the material of the anode 40 is a material known in the art for use in the anode. The material of the cathode 20 and the material of the anode 40 can refer to the relevant description above, and it will not be repeated here.

The light-emitting layer 30 may be a quantum dot light-emitting layer, and at this time, the photoelectric device 100 may be a quantum dot photoelectric device. The thickness of the light-emitting layer 30 may be in the thickness range of the light-emitting layer in a quantum dot photoelectric device known in the art, and may be, for example, 5 nm to 100 nm, such as 5 nm, 10 nm, 20 nm, 50 nm, 80 nm, 100 nm, and the like. Alternatively, the thickness range of the light-emitting layer may be 60˜100 nm.

Moreover, the material of the quantum dot light-emitting layer is a quantum dot known in the art for the quantum dot light-emitting layer. For example, the material of the quantum dot light-emitting layer is one of a red quantum dot, a green quantum dot, and a blue quantum dot. The quantum dots may be selected from, but are not limited to, one or more of a single structure quantum dot and a core-shell structure quantum dot. For example, the quantum dot may be selected from, but not limited to, one or more of Group II-VI compound, Group III-V compound, and Group I-III-VI compound. The Group II-VI compound is selected from one or more of CdSe, CdS, CdTe, ZnSe, ZnS, CdTe, ZnTe, CdZnS, CdZnSe, CdZnTe, ZnSeS, ZnSeTe, ZnTeS, CdSeS, CdSeTe, CdTeS, CdZnSeS, CdZnSeTe, and CdZnSTe. The Group III-V compound is selected from InP, InAs, GaP, GaAs, GaSb, AlN, AIP, InAsP, InNP, InNSb, GaAlNP, and InAINP. The group I-III-VI compound is selected from one or more of CuInS₂, CuInSe₂, and AgInS₂.

The hole transport thin film 10 can be described above with reference to the above description, and will not be repeated here.

In some embodiments, the hole transport thin film 10 of the photoelectric device 100 includes the first polymer and the second polymer. The second polymers including fluorene-containing groups tend to be enriched at the interface between the hole transport thin film 10 and air (a side of the hole transport thin film 10 close to the light-emitting layer), and extend into the air, so that the hole transport thin film 10 forms a gradient molecular structure from the bottom layer (a layer of the hole transport thin film 10 close to the anode) to the top layer (a layer of the hole transport thin film 10 close to the light-emitting layer). The closer to the top layer, the greater the content of the second polymer, and the closer to the bottom layer, the greater the content of the first polymer. There are relatively more aniline-containing groups in the first polymer and relatively few aniline-containing groups in the second polymer, thereby the HOMO energy level of the first polymer is higher, and the HOMO energy level of the second polymer is lower. Corresponding to the gradient molecular structure of the thin film from the bottom layer to the top layer, the hole transport thin film 10 forms a gradient energy level from high to low from the bottom layer to the top layer. The high HOMO energy level of the bottom layer matches the anode 40, which facilitates the anode 40 to inject holes into the hole transport thin film 10. The low HOMO energy level of the top layer reduces the energy level difference between the hole transport thin film 10 and the light-emitting layer 40, making it easier for holes to overcome the potential barrier between the hole transport thin film 10 and the light-emitting layer 40 and transition to the light-emitting layer 40. In addition, the inside of the thin film has a gradient molecular structure which is not a traditional double-layer transport thin film, thereby there is no interfacial mutual dissolution problems between material interface and between different transport thin film layers. Therefore, the hole transport thin film 10 prepared by the embodiment of the present disclosure can be improved with hole mobility, and there is no problem of interfacial mutual dissolution.

In yet another embodiment, the hole transport thin film 10 of the photoelectric device 100 includes a first polymer and a third polymer. The first polymers including the fluorene-containing groups tend to be enriched at the interface between the hole transport thin film 10 and the air (a side close to the light-emitting layer), and extend into the air, thereby the hole transport thin film 10 can form a gradient molecular structure from the bottom layer (a layer of the hole transport thin film 10 close to the hole injection layer) to the top layer (a layer of the hole transport thin film 10 close to the light-emitting layer). The closer to the bottom layer, the greater the content of the third polymer, and the closer to the top layer, the greater the content of the first polymer. The first polymer contains the electron-donating group, thereby the LUMO energy level of the top layer of the hole transport thin film 10 can be improved, that is the LUMO energy level of the top layer of the hole transport thin film 10 is improved. Thereby the difficulty of electron transition from the light-emitting layer to the hole transport layer is increased, so that the aging rate of the hole transport layer can be reduced, and the life of the photoelectric device can be improved. As an example, the content of the third polymer decreases and the content of the first polymer increases from the first surface (toward the anode 40) to the second surface (toward the light-emitting layer 30) of the hole transport thin film 10. The fluorine-containing groups of the first polymer tend to be enriched to the surface of the hole transport thin film 10 (that is, a surface of the hole transport thin film 10 close to the light-emitting layer), thereby the hole transport thin film 10 can form a gradient molecular structure from the bottom layer (a layer of the hole transport thin film 10 close to the hole injection layer) to the top layer (a layer of the hole transport thin film 10 close to the light-emitting layer). The closer to the bottom layer, the greater the content of the third polymer, and the closer to the top layer, the greater the content of the first polymer. The first polymer mainly located in the top layer contains the electron-donating group, thereby the LUMO energy level of the top layer of the hole transport thin film 10 can be improved. Corresponding to the gradient molecular structure from the bottom layer to the top layer, the hole transport thin film 10 can form a gradient LUMO energy level that gradually increases from the bottom layer to the top layer. The increase of LUMO energy level in the top layer of the hole transport thin film 10 increases the difficulty of electron transition from the light-emitting layer to the hole transport layer, which can reduce the aging rate of the hole transport layer and improve the lifetime of the photoelectric device 100.

In yet another embodiment, the hole transport thin film 10 of the photoelectric device 100 includes the first polymer and the crosslinking compound. The second crosslinking group in the crosslinking compound can undergo a crosslinking reaction with the first crosslinking group in the first polymer. The crosslinking compound contains at least two second crosslinking groups and the first polymer contains one first crosslinking group, thereby the crosslinking compound can connect at least two first polymer molecules to form a cross-linked structure in the hole transport thin film 10. At the same time, due to the presence of fluorine atoms in the crosslinking compound, the crosslinking compounds tend to be enriched at the upper layer of the hole transport thin film 10 (referring to the structure of FIG. 1), that is, the surface close to the light-emitting layer mainly includes cross-linked structure. The cross-linked structure has good solvent resistance, thereby it is possible to prevent the material component of the light-emitting layer from penetrating into the hole transport thin film 10. Therefore, the hole transport thin film 10 prepared by the embodiment of the present disclosure can reduce the occurrence of interfacial mutual dissolution between the hole transport thin film 10 and the light-emitting layer, thereby improving the current efficiency of the photoelectric device.

As an example, from the first surface (toward the anode 40) to the second face (toward the light-emitting layer 30) of the hole transport thin film 10, the content of the first polymer decreases and the content of the crosslinking compound increases. The fluorine-containing groups tend to be enriched to the surface of the hole transport thin film 10 (that is, a surface of the hole transport thin film 10 close to the light-emitting layer), thereby the hole transport thin film 10 can form a gradient molecular structure from the bottom layer (a layer of the hole transport thin film 10 close to the hole injection layer) to the top layer (a layer of the hole transport thin film 10 close to the light-emitting layer). The closer to the bottom layer, the greater the content of the first polymer, that is, the surface of the hole transport thin film 10 close to the hole injection layer mainly includes non-cross-linked structure. The closer to the top layer, the more crosslinking compounds, and the cross-linked structure formed by the crosslinking compounds can prevent the material components of the light-emitting layer from penetrating into the hole transport thin film 10, thereby reducing the occurrence of interfacial mutual dissolution between the hole transport thin film 10 and the light-emitting layer, thus improving the current efficiency of the photoelectric device.

In some embodiments, the hole transport thin film 10 of the photoelectric device 100 includes a first polymer and a fourth polymer. The HOMO energy level of the hole transport thin film 10 can be in a range from −5.8 eV to −4.8 eV, which is located between the HOMO energy level of the hole injection layer and the HOMO energy level of the light-emitting layer, thereby the requirement that the hole injection layer injects holes into the light-emitting layer can be satisfied. Furthermore, during the film formation process, due to the presence of fluorine atoms, the fourth polymers tends to be enriched at the interface between the hole transport thin film 10 and the air (a side of the hole transport thin film 10 close to a light-emitting layer), and extends into the air. The closer to the top layer, the greater the content of the fourth polymer. At the same time, since the fourth polymer further includes self-crosslinking group, crosslinking reaction may occur between the block copolymer molecules of the fourth polymer when the hole transport thin film 10 is formed, so that the layer of the hole transport thin film 10 close to the light-emitting layer mainly includes cross-linked polymer. The cross-linked polymer has better solvent resistance, can prevent the material components of the light-emitting layer from penetrating into the hole transport thin film 10, and can reduce the interfacial mutual dissolution between the hole transport thin film 10 and the light-emitting layer, so as to improve the current efficiency of the device. As an example, from the first surface (toward the anode 40) to the second face (toward the light-emitting layer 30) of the hole transport thin film 10, the content of the first polymer decreases and the content of the fourth polymer increases. Due to the presence of fluorine atoms, the fourth polymers tend to be enriched to the surface of the hole transport thin film 10 (that is, a surface of the hole transport thin film 10 close to the light-emitting layer), thereby the hole transport thin film 10 can form a gradient molecular structure from the bottom layer (a layer of the hole transport thin film 10 close to the hole injection layer) to the top layer (a layer of the hole transport thin film 10 close to the light-emitting layer). The closer to the bottom layer, the greater the content of the first polymer, that is, the surface of the hole transport thin film 10 close to the hole injection layer mainly includes non-cross-linked structure. The closer to the top layer, the more the fourth polymer, and the cross-linked structure formed by the fourth polymer can prevent the material components of the light-emitting layer from penetrating into the hole transport thin film 10, thereby reducing the occurrence of interfacial mutual dissolution between the hole transport thin film 10 and the light-emitting layer, thus improving the current efficiency of the photoelectric device.

Referring to FIG. 1, in one embodiment, the photoelectric device 100 may further include a hole injection layer (HIL) 50. The hole injection layer 50 is disposed between the hole transport thin film 10 and the anode 40. A material of the hole injection layer 50 may be selected from materials having hole injection capabilities, which including, but not limited to, one or more of PEDOT:PSS, MCC, CuPc, F4-TCNQ, HATCN, transition metal oxides, and transition metal chalcogenides. PEDOT:PSS is a high molecular polymer with a name of poly(3, 4-ethylenedioxythiophene)-poly (styrenesulfonic acid). A thickness of the hole injection layer 50 may be, for example, 10 nm to 100 nm, such as 10 nm, 20 nm, 30 nm, 40 nm, 50 nm, 60 nm, 100 nm, and the like.

Referring to FIG. 1, in one embodiment, the photoelectric device 100 may further include an electron transport layer 60. The electron transport layer 60 is disposed between the cathode 20 and the light-emitting layer 30. The electron transport layer 60 may be an oxide semiconductor nanomaterial having electron transport capability. The oxide semiconductor nanomaterial may be selected from, but not limited to, one or more of ZnO, TiO₂, SnO₂, Ta₂O₃, ZrO₂, NiO, TiLiO, ZnAlO, ZnMgO, ZnSnO, ZnLiO, and InSnO.

It can be understood that in addition to the above-described functional layers, the photoelectric device 100 may also include some functional layers conventionally used for photoelectric devices that contribute to improving the performance of the photoelectric device, such as an electron blocking layer, a hole blocking layer, an electron injection layer, an interface modification layer, and the like. It can be understood that the material and thickness of each layer of the photoelectric device 100 can be adjusted according to the light emission requirements of the photoelectric device 100.

In some embodiments of the present disclosure, the photoelectric device 100 is a quantum dot light-emitting diode with a structure of glass substrate-anode-(hole injection layer)-hole transport layer-quantum dot light-emitting layer-electron transport layer-cathode. Moreover, the hole injection layer is an optional option, that is the structure of the quantum dot light-emitting diode may or may not include the hole injection layer.

An embodiment of the present disclosure also provides a display device including the photoelectric device provided in the present disclosure. The display device may be any electronic product having a display function. The electronic product includes, but not limited to, a smartphone, a tablet computer, a notebook computer, a digital camera, a digital video camera, a smart wearable device, a smart weighing electronic scale, a vehicle-mounted display, a television, or an electronic book reader. The smart wearable device may be, for example, a smart bracelet, a smart watch, a virtual reality (VR) helmet, and the like.

The present disclosure is described in detail below by way of specific Examples, Comparative Examples, and Experimental Examples. The specific embodiments are only partial embodiments of the present disclosure and are not limited to the present disclosure.

### Example 1

This Example provides a quantum dot light-emitting diode and a preparation method thereof. The structural of the quantum dot light-emitting diode refers to FIG. 1. The quantum dot light-emitting diode of this Example includes a cathode 20, an electron transport layer 60, a light-emitting layer 30, a hole transport thin film 10, a hole injection layer 50, and an anode 40 which are stacked in an order that from top to bottom.

Materials of each layer of the quantum dot light-emitting diode are as following:

The material of the cathode 20 is Al, and the thickness of the cathode 20 is 25 nm.

The material of the electron transport layer 60 is Zn_{0.9}Mg_{0.1}O.

The material of the light-emitting layer 30 is nano-CdZnSe.

The material of the hole transport thin film 10 includes a first polymer and a second polymer. A mass fraction of the first polymer is 15%, wherein the molar fraction of the aniline-containing group is 60%. The mass fraction of the second polymer is 85%, wherein the mole fraction of the aniline-containing group is 1%.

The material of the hole injection layer 50 is PEDOT:PSS.

The material of the anode 40 is ITO, the thickness of the anode 40 is 100 nm, and a glass substrate is disposed on a surface of the anode 40.

The preparation method of the quantum dot light-emitting diode in this Example includes the following steps:

Preparing a material of the hole transport thin film 10: dissolving a first polymer and a second polymer in chlorobenzene to obtain a hole transport material solution.

Preparing an anode 40 on a glass substrate.

Spin-coating PEDOT:PSS on the surface of the anode 40 away from the glass substrate with a rotational speed of 5000 for 30 seconds, then annealing by heating at 200° C. for 15 minutes to obtain a hole injection layer 50.

Spin-coating the hole transport material solution on the surface of the hole injection layer 50 away from the anode 40 with a rotational speed of 3000 for 30 seconds, then drying at 90° C., and annealing at 140° C. to obtain a hole transport thin film 10.

Spin-coating CdZnSe quantum dots on the surface of the hole transport thin film 10 away from the hole injection layer 50, and annealing to obtain a light-emitting layer 30.

Spin-coating Zn_{0.9}Mg_{0.1}O on the surface of the light-emitting layer 30 away from the hole transport thin film 10, then annealing to obtain an electron transport layer 60.

Preparing an Al cathode 20 on the surface of the electron transport layer 60 away from the light-emitting layer 30 by a vapor deposition method.

### Example 2

This Example provides a quantum dot light-emitting diode and a preparation method thereof. Compared with the quantum dot light-emitting diode of Example 1, the difference is that: in the first polymer, the molar fraction of the aniline-containing is 75%; in the second polymer, the molar fraction of the aniline-containing group is 20%.

### Example 3

This Example provides a quantum dot light-emitting diode and a preparation method thereof. Compared with the quantum dot light-emitting diode of Example 1, the difference is that: in the first polymer, the molar fraction of the aniline-containing is 90%; in the second polymer, the molar fraction of the aniline-containing group is 40%.

### Example 4

This Example provides a quantum dot light-emitting diode and a preparation method thereof. The structural of the quantum dot light-emitting diode refers to FIG. 1. The quantum dot light-emitting diode of this Example includes a cathode 20, an electron transport layer 60, a light-emitting layer 30, a hole transport thin film 10, a hole injection layer 50, and an anode 40 which are stacked in an order that from top to bottom.

Materials of each layer of the quantum dot light-emitting diode are as following:

The material of the cathode 20 is Al.

The material of the electron transport layer 60 is Zn_{0.7}Mg_{0.3}O.

The material of the light-emitting layer 30 is nano-ZnS.

The material of the hole transport thin film 10 includes a third polymer (60% wt) and a first polymer (40% wt). The third polymer is TFB. A structural formula of the first polymer is as following: where R₁′ to R₃′ are alkyls containing 5 carbon atoms; R₄′ is an imidazole group, and the mole fraction in the second polymer is 3%; R₅′ is an alkene containing 6 carbon atoms, and partially H atoms are substituted.

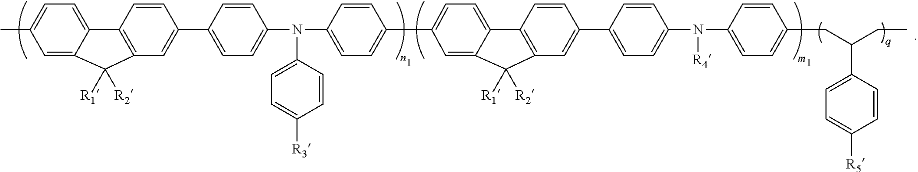

The material of the hole injection layer 50 is PEDOT:PSS.

The material of the anode 40 is ITO, the thickness of the anode 40 is 100 nm, and a glass substrate is disposed on a surface of the anode 40.

The preparation method of the quantum dot light-emitting diode in this Example includes the following steps:

Preparing a material of the hole transport thin film 10: dissolving a first polymer and a third polymer in cyclohexylbenzene to obtain a hole transport material solution (13 mg/mL).

Preparing an anode 40 on a glass substrate.

Spin-coating PEDOT:PSS on the surface of the anode 40 away from the glass substrate with a rotational speed of 5000 for 30 seconds, then annealing by heating at 200° C. for 15 minutes to obtain a hole injection layer 50.

Spin-coating the hole transport material solution on the surface of the hole injection layer 50 away from the anode 40 with a rotational speed of 3000 for 30 seconds, then drying at 40° C., and annealing at 230° C. to obtain a hole transport thin film 10.

Spin-coating CdZnSe quantum dots on the surface of the hole transport thin film 10 away from the hole injection layer 50, and annealing to obtain a light-emitting layer 30.

Spin-coating Zn_{0.9}Mg_{0.1}O on the surface of the light-emitting layer 30 away from the hole transport thin film 10, then annealing to obtain an electron transport layer 60.

Preparing an Al cathode 20 on the surface of the electron transport layer 60 away from the light-emitting layer 30 by a vapor deposition method.

Moreover, after the heat treatment of the hole transport thin film 10 is completed, the LUMO energy level of the hole transport thin film 10 is a gradual energy level, and the LUMO energy level of the surface of the hole transport thin film 10 close to the light-emitting layer 30 can reach-2.1 eV. The energy level schematic diagram can refer to FIG. 7.

### Example 5

This Example provides a quantum dot light-emitting diode and a preparation method thereof. Compared with the quantum dot light-emitting diode of Example 4, the difference is that: in the material of the hole transport thin film 10, the substituent R₄′ of the first polymer is different, R₄′ is a carbazole group, and the molar fraction of R₄′ in the first polymer is 15%.

Moreover, after the heat treatment of the hole transport thin film 10 is completed, the LUMO energy level of the hole transport thin film 10 is a gradual energy level, and the LUMO energy level of the surface of the hole transport thin film 10 close to the light-emitting layer 30 can reach-2.0 eV. The energy level schematic diagram can refer to FIG. 8.

### Example 6

This Example provides a quantum dot light-emitting diode and a preparation method thereof. Compared with the quantum dot light-emitting diode of Example 4, the difference is that: the material of the hole transport thin film 10 includes a third polymer (80% wt) and a first polymer (20% wt), the third polymer is polyaniline and derivatives thereof; in the first polymer, R₁′ to R₃′ are methyls, R₄′ is triazole, and the molar fraction of R₄′ in the first polymer is 5%, R₅′ is phenylpropylcyclobutane containing 12 carbon atoms.

### Example 7

This Example provides a quantum dot light-emitting diode and a preparation method thereof. The structural of the quantum dot light-emitting diode refers to FIG. 1. The quantum dot light-emitting diode of this Example includes a cathode 20, an electron transport layer 60, a light-emitting layer 30, a hole transport thin film 10, a hole injection layer 50, and an anode 40 which are stacked in an order that from top to bottom.

Materials of each layer of the quantum dot light-emitting diode are as following:

The material of the cathode 20 is Al, and the thickness of the cathode 20 is 25 nm.

The material of the electron transport layer 60 is Zn_{0.7}Mg_{0.3}O.

The material of the light-emitting layer 30 is nano-ZnS.

The material of the hole transport thin film 10 includes a first polymer (95% wt) and a cross-linking polymer (5% wt). The first polymer has a structural formula as described above, a weight average molecular weight of the first polymer is 90,000, and a molecular weight dispersion index is 2.8.

A structural formula of the first polymer is as following:

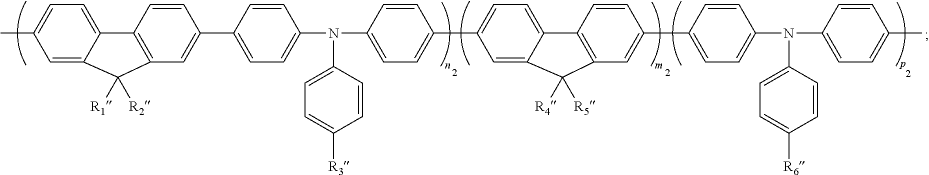

R₁″ to R₅″ are alkyls containing 3 carbon atoms, and R₆″ contains benzocyclobutane;
The structural formula of the crosslinking compound is R₈″—R₉″—R₁₀″, partially of the hydrogen atoms in the crosslinking compound is substituted by fluorine; R₉″ is an alkyl main chain containing 6 carbon atoms; R₈″ and R₁₀″ are same crosslinking groups, and the structural formula of the crosslinking group is as following:

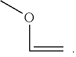

The material of the hole injection layer 50 is PEDOT:PSS.

The material of the anode 40 is ITO, the thickness of the anode 40 is 100 nm, and a glass substrate is disposed on a surface of the anode 40.

The preparation method of the quantum dot light-emitting diode in this Example includes the following steps:

Preparing a material of the hole transport thin film 10: dissolving a first polymer and a crosslinking polymer in ethyl benzoate to obtain a hole transport material solution (12 mg/mL).

Preparing an anode 40 on a glass substrate.

Spin-coating PEDOT:PSS on the surface of the anode 40 away from the glass substrate with a rotational speed of 5000 for 30 seconds, then annealing by heating at 200° C. for 15 minutes to obtain a hole injection layer 50.

Spin-coating the hole transport material solution on the surface of the hole injection layer 50 away from the anode 40 with a rotational speed of 3000 for 30 seconds, then drying at 90° C., and annealing at 140° C. to obtain a hole transport thin film 10.

Spin-coating CdZnSe quantum dots on the surface of the hole transport thin film 10 away from the hole injection layer 50, and annealing to obtain a light-emitting layer 30.

Spin-coating Zn_{0.9}Mg_{0.1}O on the surface of the light-emitting layer 30 away from the hole transport thin film 10, then annealing to obtain an electron transport layer 60.

Preparing an Al cathode 20 on the surface of the electron transport layer 60 away from the light-emitting layer 30 by a vapor deposition method.

### Example 8

This Example provides a quantum dot light-emitting diode and a preparation method thereof. Compared with the quantum dot light-emitting diode of Example 7, the difference is that: the material of the hole transport thin film 10 includes a first polymer (99% wt) and a crosslinking polymer (1% wt); the first polymer has a structural formula as described above, a weight average molecular weight of the first polymer is 100,000, and a molecular weight dispersion index is 1.8; R₁″ to R₅″ are alkyls containing 10 carbon atoms, and R₆″ contains cyclohexane; the crosslinking compound has a structural formula as described above, R₉″ is an alkyl main chain containing 3 carbon atoms, and R₈″ and R₁₀″ are primary amine group.

### Example 9

This Example provides a quantum dot light-emitting diode and a preparation method thereof. Compared with the quantum dot light-emitting diode of Example 7, the difference is that: the material of the hole transport thin film 10 includes a first polymer (97% wt) and a crosslinking polymer (3% wt); the first polymer has a structural formula as described above, a weight average molecular weight of the first polymer is 120,000, and a molecular weight dispersion index is 2.4; R₁″, R₂″, R₄″ and R₅″ are alkyls containing 10 carbon atoms, R₃″ is alkyl containing 15 carbon atoms, and R₆″ contains cyclohexane; the crosslinking compound has a structural formula as described above, R₉″ is an alkyl main chain containing 6 carbon atoms, and R₈″ and R₁₀″ are same crosslinking group and have the following structural formula:

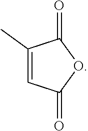

### Example 10

This Example provides a quantum dot light-emitting diode and a preparation method thereof. The structural of the quantum dot light-emitting diode refers to FIG. 1. The quantum dot light-emitting diode of this Example includes a cathode 20, an electron transport layer 60, a light-emitting layer 30, a hole transport thin film 10, a hole injection layer 50, and an anode 40 which are stacked in an order that from top to bottom.

Materials of each layer of the quantum dot light-emitting diode are as following:

The material of the cathode 20 is Al.

The material of the electron transport layer 60 is Zn_{0.8}Mg_{0.2}O.

The material of the light-emitting layer 30 is nano-ZnSe.

The material of the hole transport thin film 10 includes a first polymer (70% wt) and a fourth polymer (30% wt).

A structural formula of the first polymer is as following:

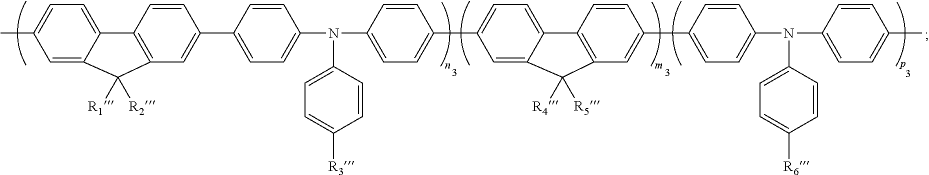

where a weight average molecular weight of the first polymer is 83,000, and a molecular weight dispersion index of the first polymer is 1.8; R₁′″, R₂′″, R₄′″ and R₅′″ are ethyls; R₃ and R₆ are alkyls containing 15 carbon atoms. A weight average molecular weight of the fourth polymer is 100,000, and a molecular weight dispersion index of the fourth polymer is 2.0; partially of the H atoms are substituted by fluorine atoms; R₁′″, R₂′″, R₄′″ and R₅′″ of the fourth polymer are ethyls; R₃′″ and R₆′″ are alkyl groups containing 10 carbon atoms; R₇′″ is olefin containing 15 carbon atoms, and the mole fraction of R₇′″ in the fourth polymer is 3%.

The material of the hole injection layer 50 is PEDOT:PSS.

The material of the anode 40 is ITO, and a glass substrate is disposed on a surface of the anode 40.

The preparation method of the quantum dot light-emitting diode in this Example includes the following steps:

Preparing a material of the hole transport thin film 10: dissolving a first polymer and a fourth polymer in ethyl benzoate to obtain a hole transport material solution (14 mg/mL).

Preparing an anode 40 on a glass substrate.

Spin-coating PEDOT:PSS on the surface of the anode 40 away from the glass substrate, then annealing to obtain a hole injection layer 50.

Spin-coating the hole transport material solution on the surface of the hole injection layer 50 away from the anode 40, then drying and annealing, heat treatment at 100° C. first, and then heat treatment at 170° C. to obtain a hole transport thin film 10.

Spin-coating ZnSe quantum dots on the surface of the hole transport thin film 10 away from the hole injection layer 50, and annealing to obtain a light-emitting layer 30.

Spin-coating Zn_{0.9}Mg_{0.1}O on the surface of the light-emitting layer 30 away from the hole transport thin film 10, then annealing to obtain an electron transport layer 60.

Preparing an Al cathode 20 on the surface of the electron transport layer 60 away from the light-emitting layer 30 by a vapor deposition method.

### Example 11

This Example provides a quantum dot light-emitting diode and a preparation method thereof. Compared with the quantum dot light-emitting diode of Example 10, the difference is that: the material of the hole transport thin film 10 includes a first polymer (60% wt) and a fourth polymer (40% wt); a weight average molecular weight of the first polymer is 78,000, and a molecular weight dispersion index of the first polymer is 1.9; R₁′″, R₂′″, R₄′″ and R₅′″ of the first polymer are methyls; R₃′″ and R₆′″ of the first polymer are alkyls containing 6 carbon atoms; a weight average molecular weight of the fourth polymer is 120,000, and a molecular weight dispersion index of the fourth polymer is 2.5; R₁′″, R₂′″, R₄′″ and R₅′″ of the fourth polymer are methyls; R₃′″ and R₆′″ of the fourth polymer are alkyls containing 18 carbon atoms; R₇′″ of the fourth polymer is phenylpropylcyclobutane containing 15 carbon atoms, and the mole fraction of R₇′″ in the fourth polymer is 4%.

### Example 12

This Example provides a quantum dot light-emitting diode and a preparation method thereof. Compared with the quantum dot light-emitting diode of Example 10, the difference is that: the material of the hole transport thin film 10 includes a first polymer (95% wt) and a fourth polymer (5% wt); a weight average molecular weight of the first polymer is 50,000, and a molecular weight dispersion index of the first polymer is 1.5; R₁′″, R₂′″, R₄′″ and R₅′″ of the first polymer are octyls; R₃′″ and R₆′″ of the first polymer are methyls; a weight average molecular weight of the fourth polymer is 90,000, and a molecular weight dispersion index of the fourth polymer is 2.2; R₁′″, R₂′″, R₄′″ and R₅′″ of the fourth polymer are octyls; R₃′″ and R₆′″ of the fourth polymer are methyls; R₇′″ of the fourth polymer is olefin containing 10 carbon atoms, and the mole fraction of R₇′″ in the fourth polymer is 2%.

### Example 13

This Example provides a thin film and a preparation method thereof, wherein the material of the film includes a first polymer, and a repeating unit of the first polymer has a structural formula shown in formula (1.1) as following:

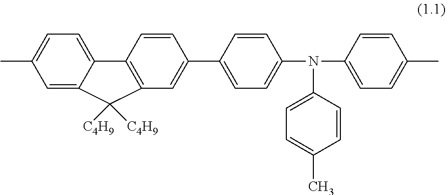

The repeating unit shown in the formula (1.1) is composed of a fluorene structural unit and a triphenylamino structural unit, and the —C₄H₉ group is n-butyl. A weight average molecular weight of the first polymer is 86,000, the ratio of the weight average molecular weight to the number average molecular weight of the first polymer is 1.5, and a glass transition temperature of the first polymer is 100° C. In the first polymer, 30% by weight of the polymer has a molecular weight of 0.9 to 1.1 times the weight average molecular weight of the first polymer, 2.5% by weight of the polymer has a molecular weight of less than 0.3 times the weight average molecular weight of the first polymer, and 2.5% by weight of the polymer has a molecular weight of more than 1.7 times the weight average molecular weight of the first polymer.

The preparation method of the thin film in this Example includes the following steps:
S1.1, dispersing the first polymer in chlorobenzene to form a first polymer-chlorobenzene solution having a concentration of 10 mg/mL;
S1.2, Providing a substrate, spin-coating the first polymer-chlorobenzene solution prepared in step S1.1 on one side of the substrate in an atmospheric environment of normal temperature and normal pressure, and then subjecting it to a constant temperature heat treatment at 150° C. for 20 minutes to obtain a thin film having a thickness of 25 nm.

### Example 14

This Example provides a thin film and a preparation method thereof. Compared with the thin film of Example 13, the thin film of this Example differs only in that: the degree of polymerization of the first polymer is different, in this Example, a repeating unit of the first polymer has a structural formula shown in formula (1.1), a weight average molecular weight of the first polymer is 60,000, the ratio of the weight average molecular weight to the number average molecular weight of the first polymer is 1.4, and a glass transition temperature of the first polymer is 80° C.; in the first polymer, 50% by weight of the polymer has a molecular weight of 0.9 to 1.1 times the weight average molecular weight of the first polymer, 2% by weight of the polymer has a molecular weight of less than 0.3 times the weight average molecular weight of the first polymer, and 2% by weight of the polymer has a molecular weight of more than 1.7 times the weight average molecular weight of the first polymer.

The preparation method of the thin film in this Example was carried out with reference to Example 13.

### Example 15

This Example provides a thin film and a preparation method thereof. Compared with the thin film of Example 13, the thin film of this Example differs only in that: the degree of polymerization of the first polymer is different, in this Example, a repeating unit of the first polymer has a structural formula shown in formula (1.1), a weight average molecular weight of the first polymer is 150,000, the ratio of the weight average molecular weight to the number average molecular weight of the first polymer is 2, and a glass transition temperature of the first polymer is 200° C.; in the first polymer, 20% by weight of the polymer has a molecular weight of 0.9 to 1.1 times the weight average molecular weight of the first polymer, 2% by weight of the polymer has a molecular weight of less than 0.3 times the weight average molecular weight of the first polymer, and 2% by weight of the polymer has a molecular weight of more than 1.7 times the weight average molecular weight of the first polymer.

The preparation method of the thin film in this Example was carried out with reference to Example 13.

### Example 16

This Example provides a thin film and a preparation method thereof. Compared with the thin film of Example 13, the thin film of this Example differs only in that: the degree of polymerization of the first polymer is different, in this Example, a repeating unit of the first polymer has a structural formula shown in formula (1.1), a weight average molecular weight of the first polymer is 120,000, the ratio of the weight average molecular weight to the number average molecular weight of the first polymer is 1.6, and a glass transition temperature of the first polymer is 180° C.; in the first polymer, 25% by weight of the polymer has a molecular weight of 0.9 to 1.1 times the weight average molecular weight of the first polymer, 1.5% by weight of the polymer has a molecular weight of less than 0.3 times the weight average molecular weight of the first polymer, and 1.5% by weight of the polymer has a molecular weight of more than 1.7 times the weight average molecular weight of the first polymer.

The preparation method of the thin film in this Example was carried out with reference to Example 13.

### Example 17

This Example provides a thin film and a preparation method thereof. Compared with the thin film of Example 13, the thin film of this Example differs only in that: the degree of polymerization of the first polymer is different, in this Example, a repeating unit of the first polymer has a structural formula shown in formula (1.1), a weight average molecular weight of the first polymer is 43,000, the ratio of the weight average molecular weight to the number average molecular weight of the first polymer is 3.6, and a glass transition temperature of the first polymer is 60° C.; in the first polymer, 5% by weight of the polymer has a molecular weight of 0.9 to 1.1 times the weight average molecular weight of the first polymer, 10% by weight of the polymer has a molecular weight of less than 0.3 times the weight average molecular weight of the first polymer, and 10% by weight of the polymer has a molecular weight of more than 1.7 times the weight average molecular weight of the first polymer.

The preparation method of the thin film in this Example was carried out with reference to Example 13.

### Example 18

This Example provides a thin film and a preparation method thereof. Compared with the thin film of Example 13, the thin film of this Example differs only in that: the degree of polymerization of the first polymer is different, in this Example, a repeating unit of the first polymer has a structural formula shown in formula (1.1), a weight average molecular weight of the first polymer is 80,000, the ratio of the weight average molecular weight to the number average molecular weight of the first polymer is 1.5, and a glass transition temperature of the first polymer is 95° C.; in the first polymer, 5% by weight of the polymer has a molecular weight of 0.9 to 1.1 times the weight average molecular weight of the first polymer, 10% by weight of the polymer has a molecular weight of less than 0.3 times the weight average molecular weight of the first polymer, and 10% by weight of the polymer has a molecular weight of more than 1.7 times the weight average molecular weight of the first polymer.

The preparation method of the thin film in this Example was carried out with reference to Example 13.

### Example 19

This Example provides a thin film and a preparation method thereof. Compared with the thin film of Example 13, the thin film of this Example differs only in that: the first polymer is different, and a repeating unit of the first polymer in this Example has a structural formula shown in formula (7.1) as following:

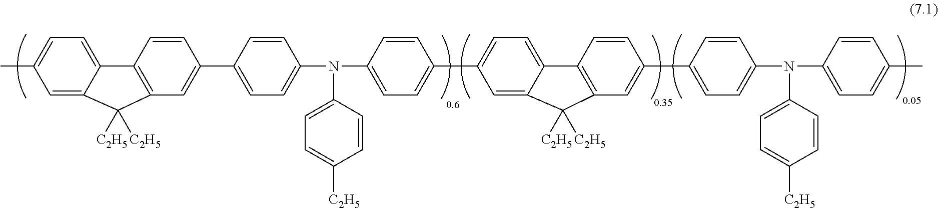

In this Example, a weight average molecular weight of the first polymer is 100,000, the ratio of the weight average molecular weight to the number average molecular weight of the first polymer is 2.0, and a glass transition temperature of the first polymer is 190° C. In the first polymer, 15% by weight of the polymer has a molecular weight of 0.9 to 1.1 times the weight average molecular weight of the first polymer, 2% by weight of the polymer has a molecular weight of less than 0.3 times the weight average molecular weight of the first polymer, and 2% by weight of the polymer has a molecular weight of more than 1.7 times the weight average molecular weight of the first polymer.

The preparation method of the thin film in this Example was carried out with reference to Example 13.

### Example 20

This Example provides a thin film and a preparation method thereof. Compared with the thin film of Example 13, the thin film of this Example differs only in that: the first polymer is different, and a repeating unit of the first polymer in this Example has a structural formula shown in formula (8.1) as following:

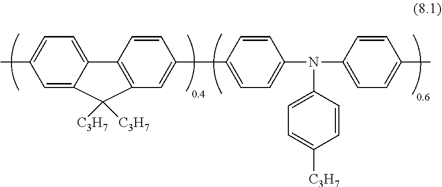

In this Example, a weight average molecular weight of the first polymer is 95,000, the ratio of the weight average molecular weight to the number average molecular weight of the first polymer is 1.4, and a glass transition temperature of the first polymer is 125° C. In the first polymer, 40% by weight of the polymer has a molecular weight of 0.9 to 1.1 times the weight average molecular weight of the first polymer, 2.5% by weight of the polymer has a molecular weight of less than 0.3 times the weight average molecular weight of the first polymer, and 2% by weight of the polymer has a molecular weight of more than 1.7 times the weight average molecular weight of the first polymer.

The preparation method of the thin film in this Example was carried out with reference to Example 13.

### Example 21

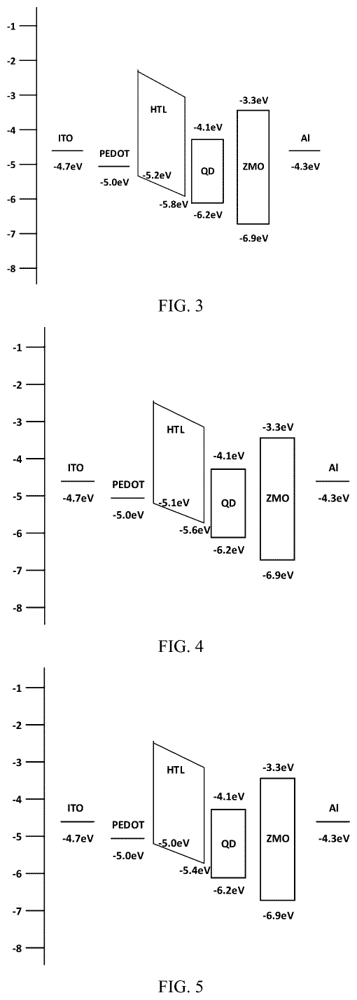

This Example provides a photoelectric device and preparation method thereof. The photoelectric device is a quantum dot light-emitting diode having an upright structure. As shown in FIG. 3, the photoelectric device includes a substrate, an anode, a hole functional layer, a light-emitting layer, an electron functional layer and a cathode which are stacked in this order in a bottom-up direction. The hole functional layer is composed of a hole injection layer and a hole transport layer which are stacked, wherein the hole injection layer is close to the anode, the hole transport layer is close to the light-emitting layer, and the electron functional layer is an electron transport layer.

The materials and thicknesses of the respective layers in the photoelectric device are as following:
The material of the substrate is glass, and the thickness of the substrate is 0.5 mm;
The material of the anode is Ag/ITO, and the thickness of the anode is Ag, wherein the thickness of the Ag layer is 100 nm, and the thickness of the ITO layer is 10 nm;

The material of the cathode is Ag, and the thickness of the cathode is 25 nm;
The material of the light-emitting layer is core-shell structure quantum dot CdZnSe/ZnSe/ZnS (the particle size is 10 nm, the surface is connected with oleic acid ligand, and the light-emitting color is green), and the thickness of the light-emitting layer is 20 nm;
The material of the electronic functional layer is nano-Zn_{0.9}Mg_{0.1}O (the average particle diameter is 7 nm), and the thickness of the electronic functional layer is 30 nm;
The material of the hole injection layer was PEDOT:PSS, and the thickness of the hole injection layer was 25 nm;
The material of the hole transport layer was a thin film prepared in Example 13, and the thickness of the hole transport layer was 25 nm.

The preparation method of the photoelectric device in the present Example includes the following steps:
S9.1, providing a substrate, sputtering ITO on one side of the substrate to obtain an ITO layer, wiping the surface of the ITO layer with a cotton swab dipped in a small amount of soapy water to remove impurities visible to the naked eye on the surface, then ultrasonically cleaning the substrate including ITO layer by deionized water for 15 minutes, acetone for 15 minutes, ethanol for 15 minutes and isopropyl alcohol for 15 minutes in sequence, drying, and then treating surface treating with UV-ozone for 15 minutes to obtain a substrate including an anode;
S9.2, spin-coating PEDOT:PSS aqueous solution on the surface of the anode away from the substrate in step S9.1 under the atmospheric environment of normal temperature and normal pressure, and then placing it at 150° C. for constant temperature heat treatment for 20 minutes to obtain a hole injection layer;
S9.3, referring to steps S1.1 and S1.2 to obtain a hole transport layer;
S9.4, spin-coating CdZnSe/ZnSe/ZnS quantum dot-n-octane solution having a concentration of 20 mg/mL on one side of the hole transport layer away from the hole injection layer in step S9.3 under a nitrogen atmosphere at normal temperature and pressure, and then placing it at 100° C. for constant temperature heat treatment for 10 minutes to obtain a light-emitting layer;
S9.5, spin-coating a nano-Zn_{0.9}Mg_{0.1}O-ethanol solution with a concentration of 30 mg/mL on one side away from the light-emitting layer in step S9.4 under a nitrogen atmosphere at normal temperature and pressure, and then placing it at 150° C. for constant temperature heat treatment for 20 minutes to obtain an electron transport layer;
S9.6, evaporating Ag on the side of the electron transport layer far away from the light-emitting layer in step S9.4 under a vacuum environment with an air pressure of 4×10⁻⁶ mbar to obtain a cathode, and then encapsulating by ultraviolet curing glue to obtain a photoelectric device.

### Example 22

This Example provides a photoelectric device and preparation method thereof. Compared with the photoelectric device of Example 21, the photoelectric device of this Example differs only in that: the material of the hole transport layer is replaced by the thin film prepared in Example 13 with the “thin film prepared in Example 14”.

The preparation method of the photoelectric device in this Example was carried out with reference to Example 21.

### Example 23

This Example provides a photoelectric device and preparation method thereof. Compared with the photoelectric device of Example 21, the photoelectric device of this Example differs only in that: the material of the hole transport layer is replaced by the thin film prepared in Example 13 with the “thin film prepared in Example 15”.

The preparation method of the photoelectric device in this Example was carried out with reference to Example 21.

### Example 24

This Example provides a photoelectric device and preparation method thereof. Compared with the photoelectric device of Example 21, the photoelectric device of this Example differs only in that: the material of the hole transport layer is replaced by the thin film prepared in Example 13 with the “thin film prepared in Example 16”.

The preparation method of the photoelectric device in this Example was carried out with reference to Example 21.

### Example 25

This Example provides a photoelectric device and preparation method thereof. Compared with the photoelectric device of Example 21, the photoelectric device of this Example differs only in that: the material of the hole transport layer is replaced by the thin film prepared in Example 13 with the “thin film prepared in Example 17”.

The preparation method of the photoelectric device in this Example was carried out with reference to Example 21.

### Example 26

This Example provides a photoelectric device and preparation method thereof. Compared with the photoelectric device of Example 21, the photoelectric device of this Example differs only in that: the material of the hole transport layer is replaced by the thin film prepared in Example 13 with the “thin film prepared in Example 18”.

The preparation method of the photoelectric device in this Example was carried out with reference to Example 21.

### Example 27

This Example provides a photoelectric device and preparation method thereof. Compared with the photoelectric device of Example 21, the photoelectric device of this Example differs only in that: the material of the hole transport layer is replaced by the thin film prepared in Example 13 with the “thin film prepared in Example 19”.

The preparation method of the photoelectric device in this Example was carried out with reference to Example 21.

### Example 28

This Example provides a photoelectric device and preparation method thereof. Compared with the photoelectric device of Example 21, the photoelectric device of this Example differs only in that: the material of the hole transport layer is replaced by the thin film prepared in Example 13 with the “thin film prepared in Example 20”.

The preparation method of the photoelectric device in this Example was carried out with reference to Example 21.

### Comparative Example 1

This Comparative Example 1 provides a quantum dot light-emitting diode and a preparation method thereof. Compared with the quantum dot light-emitting diode of Example 1, the quantum dot light-emitting diode of this Comparative Example 1 differ only in that: the materials of the hole transport thin film 10 are different, and the material of the hole transport thin film 10 in Comparative Example 1 is TFB.

### Comparative Example 2

This Comparative Example provides a quantum dot light-emitting diode and a preparation method thereof. Compared with the quantum dot light-emitting diode of Example 7, the quantum dot light-emitting diode of this Comparative Example differ only in that: the materials of the hole transport thin film 10 are different, and the material of the hole transport thin film 10 in this Comparative Example is cross-linked TFB.

### Comparative Example 3

This Comparative Example provides a quantum dot light-emitting diode and a preparation method thereof. Compared with the quantum dot light-emitting diode of Example 7, the quantum dot light-emitting diode of this Comparative Example differ only in that: the materials of the hole transport thin film 10 are different, and the material of the hole transport thin film 10 in this Comparative Example is non-cross-linked TFB.

### Comparative Example 4

This Comparative Example provides a quantum dot light-emitting diode and a preparation method thereof. Compared with the quantum dot light-emitting diode of Example 1, the quantum dot light-emitting diode of this Comparative Example differ only in that: the materials of the hole transport thin film 10 are different, and the material of the hole transport thin film 10 in this Comparative Example is cross-linked TFB.

### Comparative Example 5

This Comparative Example provides a quantum dot light-emitting diode and a preparation method thereof. Compared with the quantum dot light-emitting diode of Example 1, the quantum dot light-emitting diode of this Comparative Example differ only in that: the materials of the hole transport thin film 10 are different, and the material of the hole transport thin film 10 in this Comparative Example is non-cross-linked TFB.

### Comparative Example 6

This Comparative Example provides a photoelectric device and preparation method thereof. Compared with the photoelectric device of Example 21, the photoelectric device of this Comparative Example differs only in that: the material of the hole transport thin film 10 is TFB.

Compared with the preparation method of Example 21, the preparation method of this Comparative Example differs only in that: step S9.3 was replaced with “spin-coating a TFB-chlorobenzene solution having a concentration of 10 mg/mL on the surface of the hole injection layer away from the anode under a nitrogen atmosphere at normal temperature and normal pressure, and then placing it at 150° C. for constant temperature heat treatment for 20 minutes to obtain a hole transport layer”.

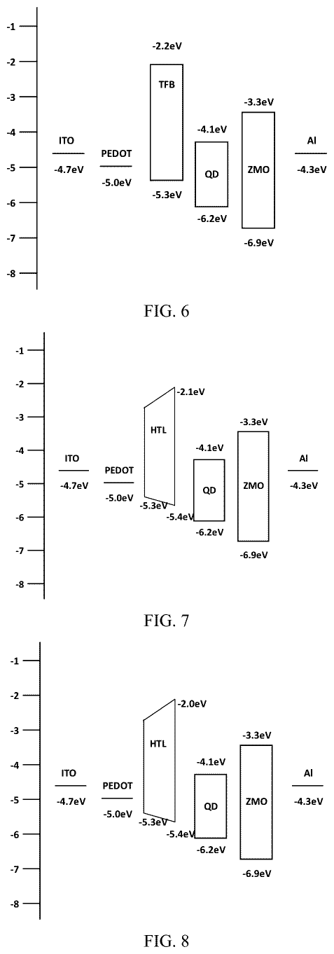

In Examples 1-3 and Comparative Example, the energy level schematic diagrams of each functional layer are shown in FIG. 3 to FIG. 6 respectively, from which the energy level of the hole transport thin film 10 can be seen, and the energy level difference between the hole injection layer 50 and the hole transport thin film 10 and the energy level difference between the hole transport thin film 10 and the light-emitting layer 30 in each example can be calculated. The calculation results are shown in Table 1, and the current efficiency test results of the photoelectric devices in Examples 1-3 and Comparative Example are also shown in Table 1.

TABLE 1

| | | HOMO energy | HOMO energy | |
|---|---|---|---|---|
| | | level difference | level difference | |
| | | between the hole | between the | |
| | HOMO energy | injection layer | hole transport | current |
| | level of hole | and the hole | thin film and | efficiency |
| | transport thin | transport thin | the light-emitting | (cd/A@ |
| Group | film (eV) | film (eV) | layer (eV) | 1000 nits) |
| Example 1 | −5.8~−5.2 | 0.2 | 0.4 | 47 |
| Example 2 | −5.1~−5.6 | 0.1 | 0.6 | 50 |
| Example 3 | −5.0~−5.4 | 0 | 0.8 | 35 |
| Comparative | −5.3 | 0.3 | 0.9 | 32 |
| Example 1 | | | | |

It can be seen from Table 1 that: gradual HOMO energy level can be realized in the hole transport thin film 10 in Examples 1-3 of the present disclosure, and the energy level difference between the hole injection layer 50 and the hole transport thin film 10 is lower than that in Comparative Example 1, which is beneficial for injecting holes from the hole injection layer 50 into the hole transport thin film 10. The energy level difference between the hole transport thin film 10 and the light-emitting layer 30 is also lower than the corresponding energy level difference in Comparative Example 1, so that holes from the hole transport thin film 10 can more easily cross the potential barrier between the hole transport thin film 10 and the light-emitting layer 30 and transition to the light-emitting layer. Combined with the current efficiency test results of the photoelectric device, it can be seen that the devices of Example 1 to Example 3 have higher current efficiencies, and the hole transport thin film 10 of the present disclosure can provide hole mobility, thereby improving the current efficiency of the corresponding photoelectric device. This is because the hole transport thin films 10 of Examples 1-3 of the present disclosure can be prepared by one wet process, and the inside of the thin films have a gradient molecular structure which is not a traditional double-layer transport thin film prepared by two wet processes, thereby there is no problem of material interface and material miscibility problems between different transport thin film layers. In summary, the hole transport thin film 10 of the embodiments of the present disclosure can improve the current efficiency of the photoelectric device.

FIG. 7 to FIG. 9 are energy level schematic diagrams of functional layers of photoelectric devices of Example 4 to Example 6, respectively.

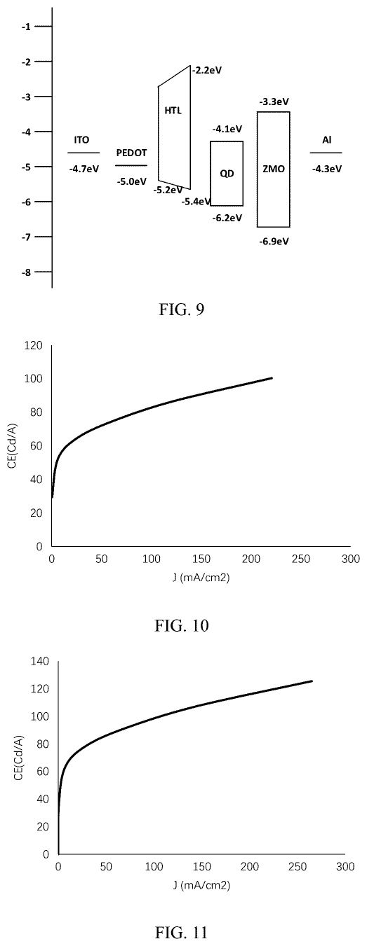

It can be seen from FIG. 9 that: the LUMO energy level of the hole transport thin film 10 after the heat treatment is completed is a gradual energy level, and the LUMO energy level of the surface of the hole transport thin film 10 close to the light-emitting layer 30 can reach-2.2 eV.

It can be seen from the energy level schematic diagrams of FIG. 7 to FIG. 9 of Example 4 to Example 6 that: the LUMO energy level of the hole transport thin film 10 is a gradual energy level; in Example 7, the LUMO energy level of the hole transport thin film 10 is increased from −3.4 eV to −2.1 eV, so that the LUMO energy level difference between the hole transport thin film 10 and the light-emitting layer is increased to 2.0 eV; in Example 8, the LUMO energy level of the hole transport thin film 10 was increased from −3.4 eV to −2.0 eV, so that the LUMO energy level difference between the hole transport thin film 10 and the light-emitting layer was increased to 2.1 eV; in Example 9, the LUMO energy level of the hole transport thin film 10 was increased from −3.4 eV to −2.2 eV, and the LUMO energy level difference between the hole transport thin film 10 and the light-emitting layer was increased to 1.9 eV.

The enlargement of the LUMO energy level difference between the hole transport thin film 10 and the light-emitting layer increases the difficulty of electron transition from the light-emitting layer to the hole transport layer, thereby the aging rate of the hole transport layer can be reduced, and thus the life of the photoelectric device can be improved.

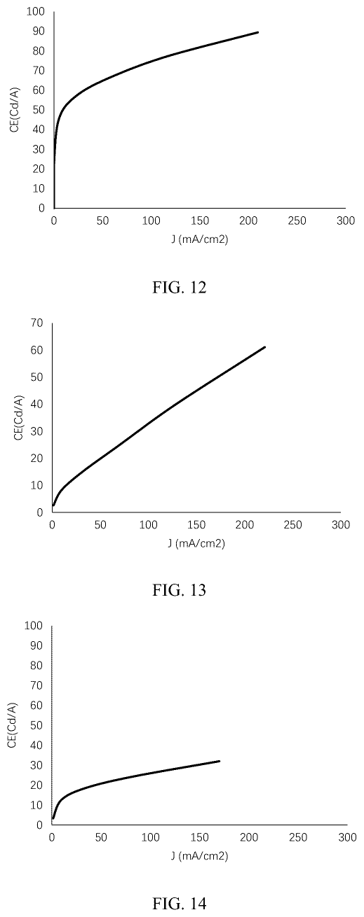

Examples 7-9 and Comparative Examples 2-3 were tested for current efficiency, and the test curves are shown in FIG. 10 to FIG. 14. It can be concluded that the maximum current efficiencies (cd/A) of Examples 7-9 and Comparative Examples 2-3 are 100, 125, 89, 61, and 32, respectively.

It can be seen from the test results that: the maximum current efficiency of Comparative Example 2 is higher than that of Comparative Example 3, which indicates that, compared with the non-cross-linked TFB hole transport thin film, the cross-linked TFB hole transport thin film can improve the current efficiency of photoelectric devices. Furthermore, the maximum current efficiencies of Examples 7-9 are higher than that of Comparative Example 2, indicating that the current efficiencies of the photoelectric devices corresponding to the hole transport thin film having the gradual cross-linked structure of Examples 7-9 of the present disclosure are higher.

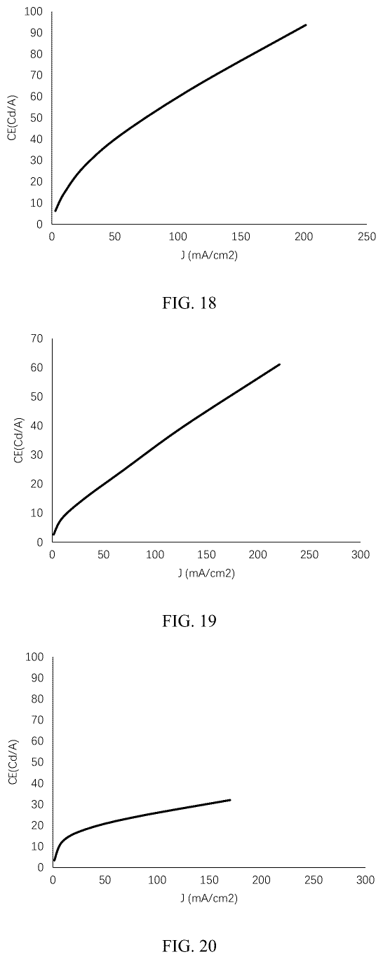

Examples 10-12 and Comparative Examples 4-5 were tested for current efficiency, and the test curves are shown in FIG. 16 to FIG. 20. It can be obtained that the maximum current efficiencies (cd/A) of Examples 10-12 and Comparative Examples 4-5 are 85, 77, 93, 61, and 32, respectively.

It can be seen from the test results that: the maximum current efficiency of Comparative Example 4 is higher than that of Comparative Example 5, which indicates that, compared with the non-cross-linked TFB hole transport thin film, the cross-linked TFB hole transport thin film can improve the current efficiency of photoelectric devices. Furthermore, the maximum current efficiencies of Examples 10-12 are higher than that of Comparative Example 4, indicating that the current efficiencies of the photoelectric devices corresponding to the hole transport thin film having the gradual cross-linked structure of Examples 10-12 of the present disclosure are higher.

### Experimental Example 1

This experimental example compares the solvent resistance characteristics of the thin film in Example 13 and the thin film in Example 18, wherein the material of the thin film in Example 13 is the first polymer A, and the material of the thin film in Example 18 is the first polymer B. The solvent resistance characteristic test includes the following steps:
S10.1, detecting to obtain fluorescence emission spectrums of the first polymer A and the first polymer B, respectively;
S10.2, the first polymer A is dispersed in chlorobenzene to prepare a first polymer A-chlorobenzene solution having a concentration of 10 mg/mL, and the first polymer B is dispersed in chlorobenzene to prepare a first polymer B-chlorobenzene solution having a concentration of 10 mg/mL, then detecting to obtain fluorescence emission spectrums of the first polymer A-chlorobenzene solution and the first polymer B-chlorobenzene solution, respectively.

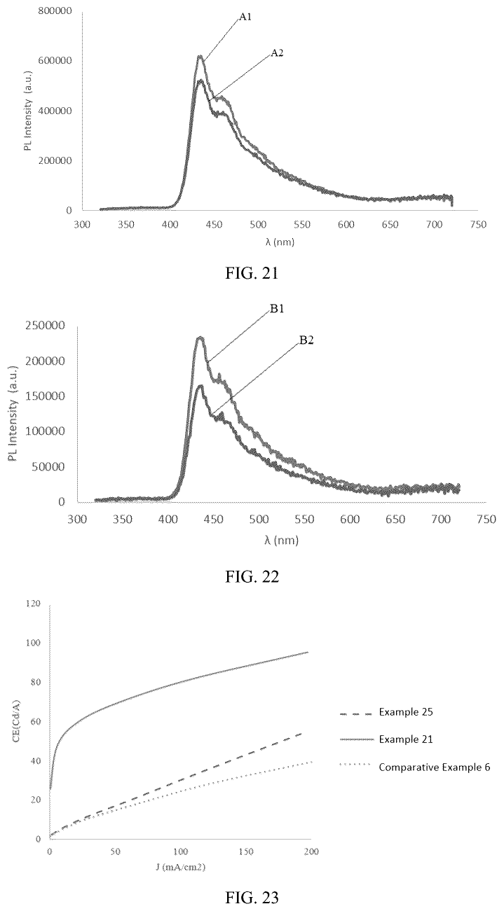

As shown in FIG. 21 and FIG. 22, the fluorescence intensity of the first polymer A (labeled A2) treated with chlorobenzene solvent is slightly decreased compared to the first polymer A (labeled A1) un-treated with chlorobenzene solvent. The fluorescence intensity of the first polymer B treated with the chlorobenzene solvent (labeled B2) also decreased compared to the first polymer B un-treated with the chlorobenzene solvent (labeled B1), and the decrease was significantly greater than that of the first polymer A treated with the chlorobenzene solvent, which indicating that the anti-solvent properties of the thin film of Example 13 are better than that of Example 18.

### Experimental Example 2

Performance testing were performed on the photoelectric devices of Examples 21 to 28 and Comparative Example, and parameters of each photoelectric device, such as voltage, current, brightness, luminescence spectrum, and the like, were detected and obtained by using Fostar FPD optical characteristic measurement equipment (efficiency testing system built by Lab View controlled QE-PRO spectrometer, Keithley 2400 and Keithley 6485). Then, the key parameters such as external quantum efficiency (EQE) and power efficiency are calculated and obtained. The lifetime of each photoelectric device is tested by lifetime testing equipment.

Moreover, the test method of external quantum efficiency is the integrating sphere test method. The lifetime test method adopts the constant current method, under the driving of constant current (2 mA current), the brightness change of each photoelectric device is tested by silicon photonic system, the time required for the brightness to decay from 100% to 95% (T95, h) is recorded, and the time required for the brightness to decay from 100% to 95% at the brightness of 1000 nits is calculated (LT95@1000 nit, h) of each photoelectric device. The current efficiency test method is as following: setting the luminous area as 2 mm×2 mm=4 mm², and intermittently collecting the brightness value of the photoelectric device in the range of driving voltage from 0 V to 8 V. The voltage value of initial collection brightness is 3 V, and it is collected every 0.2 V. The brightness value of each collection is divided by the corresponding current density to obtain the current efficiency of the photoelectric device under the collection condition, thereby the maximum current efficiency under the energization condition of the voltage of 0V to 8V is obtained.

The performance test data of the maximum current efficiency (CE@max, cd/A) of each photoelectric device are detailed in Table 2:

TABLE 2
Summary of Performance Test Data of Photoelectric
Devices of Examples 21-28 and Comparative Example 6

| Serial number | CE@max(cd/A) |
|---|---|
| Example 21 | 95 |
| Example 22 | 85 |
| Example 23 | 90 |
| Example 24 | 81 |
| Example 25 | 55 |
| Example 26 | 72 |
| Example 27 | 84 |
| Example 28 | 79 |
| Comparative | 40 |
| Example 6 | |

It can be seen from Table 1 that the optoelectronic performance of the photoelectric devices in Examples 21-28 is obviously superior to that of the photoelectric devices in Comparative Example. Taking Example 21 as an example, the CE@max of the photoelectric device in Example 21 is 2.4 times that of Comparative Example 6, which fully demonstrates that: the anti-solvent characteristics of the hole transport layer can be improved by adopting the thin film of the embodiment of the present disclosure as the hole transport layer material of the photoelectric device; when both the hole transport layer and the light-emitting layer of the photoelectric device are prepared by the solution method, the problem of “mutual dissolution” between the hole transport layer and the light-emitting layer can be improved, thereby improving the optoelectronic performance of the photoelectric device.

It can be seen from the experimental data of Examples 21-25 that the maximum current efficiencies of the photoelectric devices of Examples 21-24 are significantly higher than that of Example 25, It can be seen from FIG. 23 that the current efficiency of the photoelectric device of Example 21 is significantly better than that of Example 25 under the same energization condition. Therefore, it is preferable that the weight average molecular weight of the first polymer in the hole transport layer is 60,000 to 150,000. If the weight average molecular weight of the first polymer is too low, the degree of improvement of the optoelectronic performance of the photoelectric device is limited, that is if the weight average molecular weight of the first polymer is less than 60,000, the degree of crosslinking of the hole transport layer is limited, and thus the degree of improvement of the anti-solvent property of the hole transport layer is limited.

It can be seen from the experimental data of Examples 21-24 and Examples 26-28 that the maximum current efficiency of the photoelectric device of Example 26 is lower than that of Examples 21-24 and Examples 27-28. It shows that: in the first polymer, it is preferable that more than 10% by weight of the polymer has a molecular weight of 0.9 to 1.1 times the weight average molecular weight of the first polymer, and no more than 5% by weight of the polymer has a molecular weight less than 0.3 times the weight average molecular weight of the first polymer or greater than 1.7 times the weight average molecular weight of the first polymer, which can further improve the solvent resistance characteristics of the hole transport layer, and thus be beneficial to improving the optoelectronic performance of the photoelectric device.

The technical solutions provided by the embodiments of the present disclosure are described in detail above. The principles and embodiments of the present disclosure have been described with reference to specific embodiments, and the description of the above embodiments is merely intended to aid in the understanding of the method of the present disclosure and its core idea. At the same time, changes may be made by those skilled in the art to both the specific implementations and the scope of disclosure in accordance with the teachings of the present disclosure. In view of the foregoing, the content of the present specification should not be construed as limiting the disclosure.

1. A thin film, comprising:
a first polymer comprising a fluorene-containing group and an aniline-containing group.

2. The thin film according to claim 1, further comprises a second polymer, wherein the content of the second polymer increases or decreases from one surface to the another surface of the thin film, the first polymer is a block copolymer formed by a fluorene-containing group and a triphenylamine-containing group, and the second polymer is a block copolymer formed by a fluorene-containing group and a triphenylamine-containing group, wherein a mole fraction of the triphenylamine-containing group in the second polymer is less than a mole fraction of the triphenylamine-containing groups in the first polymer, and hydrogen atoms in the second polymer are wholly or partially substituted with fluorine atoms.

3. The thin film according to claim 2, wherein the mole fraction of the triphenylamine-containing group in the first polymer is greater than or equal to 50% and less than 100%;
the mole fraction of the triphenylamine-containing group in the second polymer is less than 50% and greater than 0;
a weight average molecular weight of the first polymer is greater than or equal to 50,000 and less than or equal to 250,000;
a weight average molecular weight of the second polymer is greater than or equal to 50,000 and less than or equal to 250,000;
a HOMO energy level of the first polymer is greater than or equal to −5.3 eV and less than −4.8 eV;
a HOMO energy level of the second polymer is greater than −5.8 eV and less than −5.3 eV;
a weight percentage of the first polymer ranges from 1% to 20%, and the weight percentage of the second polymer ranges from 80% to 99%.

4. The thin film according to claim 2, wherein structural formulas of the first polymer and the second polymer are as following: 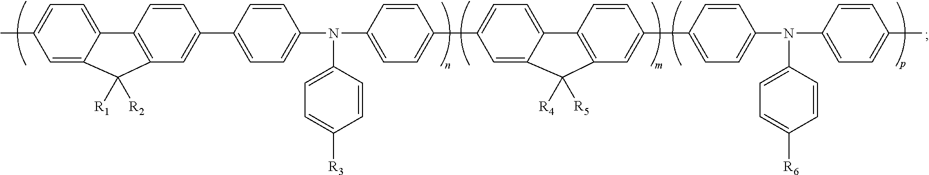
where n>0, m≥0, p≥0, R₁ to R₆ are same groups or different groups, and R₁ to R₆ are independently selected from a C₁-C₂₀ alkyl, an aromatic group, or a heteroaromatic group.

5. The thin film according to claim 1, further comprising a third polymer made of a conductive polymer material;
wherein the first polymer is a block polymer comprising a first block and a second block, the first block is a copolymerized block formed by the fluorene-containing group and the aniline-containing group, the second block is a copolymerized block formed by the fluorene-containing group and the aniline-containing group, and the aniline-containing group in the second block is connected with an electron-donating group;
hydrogen atoms in the first polymer are wholly or partially substituted with fluorine atoms.

6. The thin film according to claim 5, wherein a content of the first polymer increases or decreases from one surface to the another surface along a thickness direction of the thin film;
a mole fraction of the second block in the first polymer is greater than or equal to 0.1% and less than or equal to 15%;
a LUMO energy level of the first polymer is greater than or equal to −2.5 eV and less than or equal to −1.8 eV;
the electron-donating group is an electron-donating group having a heterocyclic structure;
the conductive polymer material is polyaniline, polythiophene, polyfluorene, or a copolymer, wherein the copolymer is formed by at least two of polyaniline, polythiophene, and polyfluorene;
a weight average molecular weight of the first polymer is greater than or equal to 50,000 and less than or equal to 250,000.

7. The thin film according to claim 5, wherein a structural formula of the first polymer is as following: 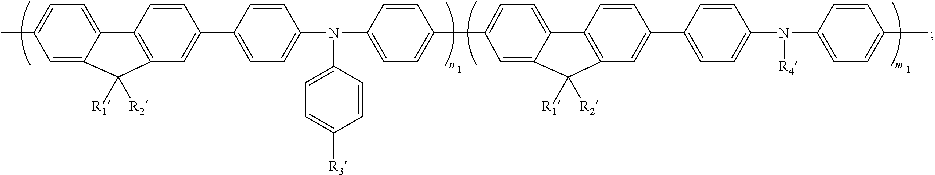
where the mole fraction of the first block is n₁, a mole fraction of the second block is m₁, and 0.001≤m₁≤0.15;
R₁′ to R₃′ are same groups or different groups, and R₁′ to R₃′ are independently selected from a C₁-C₂₀ alkyl, an aromatic group, or a heteroaromatic group;
R₄′ is an electron-donating group with a heterocyclic structure.

8. The thin film according to claim 5, wherein the first polymer further comprises a third block comprising a self-crosslinking group.

9. The thin film according to claim 8, wherein a structural formula of the first polymer is as following: 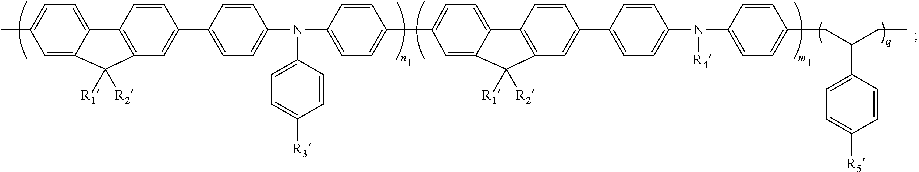
where the mole fraction of the third block is q, 0<q≤0.05, and R₅′ is a group containing a crosslinking bond.

10. The thin film according to claim 9, wherein R₅′ is one of the following structural formulas; 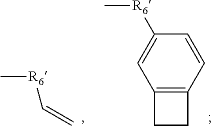
where R₆′ is a C₁-C₂₀ alkyl; or R₆′ is a C₁-C₂₀ alkyl, and one or more carbon atoms are substituted with heteroatoms, and when a plurality of carbon atoms are substituted with heteroatoms, the heteroatoms are located in a non-adjacent position;
R₄′ selected from one or more of a carbazole group, a triazole group, and a triazine group.

11. The thin film according to claim 1, further comprising a crosslinking compound;
wherein the first polymer comprises a fluorene-containing group, an aniline-containing group, and a group containing a first crosslinking group;
the crosslinking compound comprises a main chain, and at least two second crosslinking groups connected to the main chain, wherein hydrogen atoms in the crosslinking compound are wholly or partially substituted with fluorine atoms, and the second crosslinking group and the first crosslinking group undergo a crosslinking reaction to cause the first polymer to form a cross-linked structure.

12. The thin film according to claim 11, wherein along a thickness direction of the thin film, a content of the crosslinking compound increases or decreases from one surface to another surface; and/or
a weight percentage of the crosslinking compound is greater than 0 and less than or equal to 5%.

13. The thin film according to claim 11, wherein a structural formula of the first polymer is as following: 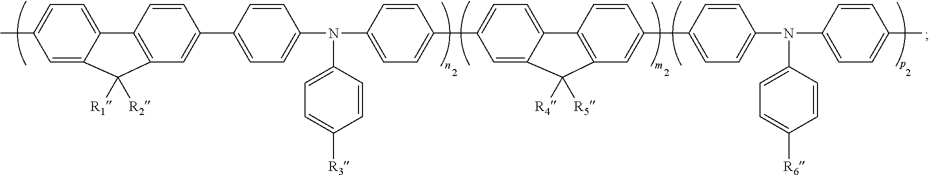
wherein n₂, m₂, and p₂ are mole fractions, n₂+m₂+p₂=1, 0<n₂<0.95, 0≤m₂<0.95, 0<p₂<0.05;
R₁″ to R₅″ are same groups or different groups, and R₁″ to R₅″ are independently selected from a C₁-C₂₀ alkyl, an aromatic group or a heteroaromatic group;
R6″ is a first crosslinking group.

14. The thin film according to claim 11, wherein a structural formula of the crosslinking compound is as following:
R₈″—R₉″—R₁₀″,
where R₉″ is a C₁-C₂₀ alkyl; or R₉″ is a C₁-C₂₀ alkyl, and one or more carbon atoms are substituted with heteroatoms, when a plurality of carbon atoms are substituted with heteroatoms, the heteroatoms are located in a non-adjacent position;
R₈″ and R₁₀″ are same or different second crosslinking groups.

15. The thin film according to claim 13, wherein R6″ is selected from any one of the following groups: 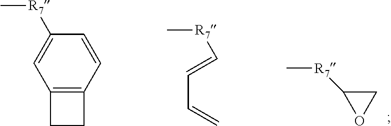
where R₇″ is a C₁-C₂₀ alkyl, an aromatic group, or a heteroaromatic group.

16. The thin film according to claim 13, wherein when R₆″ is 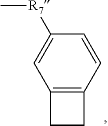
R₈″ and R₁₀″ are each independently selected from any one of the following groups: 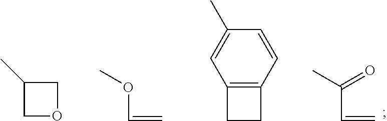
and/or
when R₆″ is 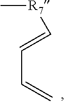
R₈″ and R₁₀″ are each independently selected from any one of the following groups: 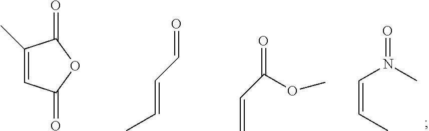
and/or
when R₆″ is 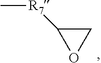
R₈″ and R₁₀″ are each independently selected from one of a primary amine group and a secondary amine group.

17. The thin film according to claim 1, further comprising a fourth polymer;
wherein the first polymer is a block copolymer formed by a fluorene-containing group and a triphenylamine-containing group;
the fourth polymer is a block copolymer formed by a fluorene-containing group, a triphenylamine-containing group, and a second self-crosslinking group, and hydrogen atoms in the fourth polymer are wholly or partially substituted with fluorine atoms.

18. The thin film according to claim 17, wherein a structural formula of the first polymer is as following: 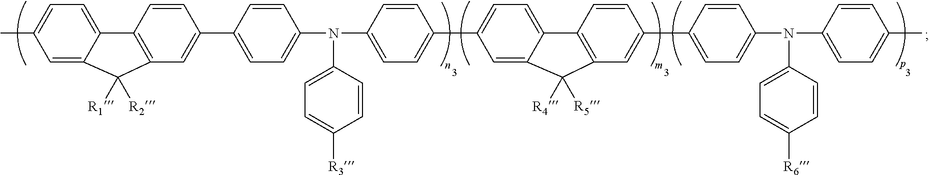
where n₃, m₃, and p₃ are molar fractions, n₃+m₃+p₃=1, 0<n₃<1, 0≤m₃<1, 0≤p₃<1; R₁′″ to R₆′″ are same groups or different groups, and R₁′″ to R₆′″ are independently selected from a C₁-C₂₀ alkyl, an aromatic group, or a heteroaromatic group.

19. The thin film according to claim 17, wherein a structural formula of the fourth polymer is as following: 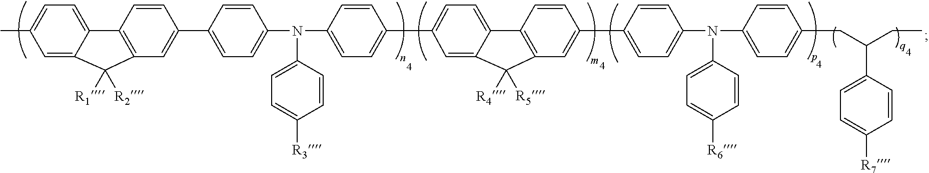
where n₄, m₄, p₄, and q₄ are molar fractions, n₄+m₄+p₄+q₄=1, 0<n₄<0.95, 0≤m₄<0.95, 0≤p₄<0.95, 0<p₄<0.05, R₁″″ to R₆″″ are same groups or different groups, R₁″″ to R₆″″ are independently selected from a C₁-C₂₀ alkyl, an aromatic group, or a heteroaromatic group, and R₇″″ contains a crosslinking bond.

20. The thin film according to claim 19, wherein R₇″″ is one of the following structural formulas: 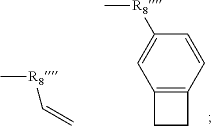
where R₈″″ is a C₁-C₂₀ alkyl; or R₈″″ is a C₁-C₂₀ alkyl, and one or more carbon atoms are substituted with heteroatoms, when a plurality of carbon atoms are substituted with heteroatoms, the heteroatoms are located in a non-adjacent position.

21. The thin film according to claim 20, wherein the content of the second polymer increases or decreases from one surface of the film to the another surface;
a mole fraction of the self-crosslinking group in the fourth polymer is greater than 0 and less than or equal to 5%;
a mole fraction of the triphenylamine-containing group in the fourth polymer is less than a mole fraction of the triphenylamine-containing group in the first polymer;
a weight percentage of the fourth polymer in the material of the thin film is greater than or equal to 5% and less than or equal to 40%.

22. The thin film according to claim 1, wherein the first polymer further comprises a heteroaryl-containing group, wherein a weight average molecular weight of the first polymer ranges from 60,000 to 150,000.

23. The thin film according to claim 22, wherein a glass transition temperature of the first polymer is 80° C. to 250° C.;
a ratio of the weight average molecular weight to the number average molecular weight of the first polymer is not greater than 2;
the aniline-containing group is selected from triphenylamine-containing group;
the heteroaryl-containing group is selected from at least one of a carbazolyl structural unit or a thienyl-containing structural unit;
a glass transition temperature of the first polymer is 120° C. to 200° C.;
more than 10% by weight of the polymer has a molecular weight of 0.9 to 1.1 times the weight average molecular weight of the first polymer, and no more than 5% by weight of the polymer has a molecular weight less than 0.3 times the weight average molecular weight of the first polymer, or no more than 5% by weight of the polymer has a molecular weight greater than 1.7 times the weight average molecular weight of the first polymer.

24. The thin film according to claim 22, wherein repeating units of the first polymer are selected from the group consisting of: 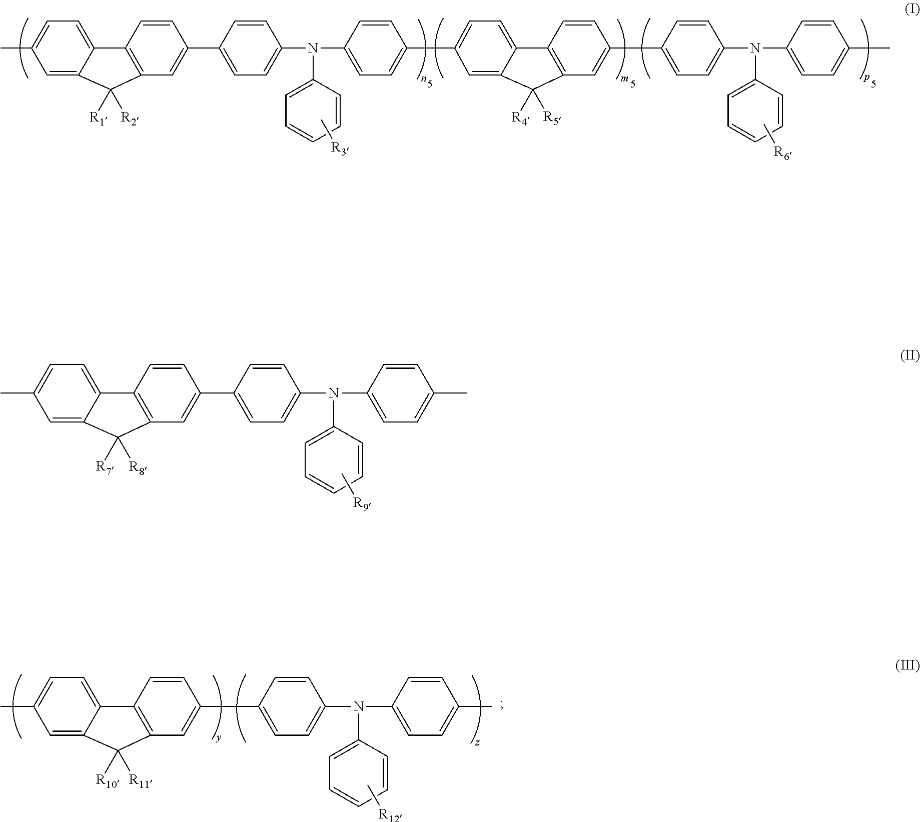
where R_{1′} to R_{20′} are independently selected from a hydrogen atom, an alkyl having 1 to 20 carbon atoms, an aryl, or a heteroaryl; n₅, m₅, p₅, y and z respectively represent mole fractions;
in the structural formula (I), the sum of m₅, n₅ and p₅ is 1, 0.5<n₅<0.9, 0.1<m₅<0.4, and 0<p₅<0.1;
in structural formula (III), the sum of y and z is 1, 0<y<0.5, and 0.5<z<1.

25. A photoelectric device comprising a cathode, a light-emitting layer, a hole transport thin film and an anode sequentially stacked, wherein the hole transport thin film is the thin film according to claim 1.

26. A display device, comprising the photoelectric device according to claim 25.
